(19) United States
(12) Patent Application Publication
(10) Pub. No.: US 2024/0258388 A1
(43) Pub. Date: Aug. 1, 2024

(54) SEMICONDUCTOR DEVICE AND A METHOD OF MANUFACTURING THE SAME

(71) Applicant: Samsung Electronics Co., Ltd., Suwon-si (KR)

(72) Inventors: Kyoungwoo LEE, Suwon-si (KR); Kyungmin KIM, Hwaseong-si (KR); Gukhee KIM, Suwon-si (KR); Beomjin KIM, Suwon-si (KR); Youngwoo KIM, Hwaseong-si (KR); Sangcheol NA, Suwon-si (KR); Anthony Dongick LEE, Suwon-si (KR); Minseung LEE, Suwon-si (KR); Myeonggyoon CHAE, Suwon-si (KR); Seungseok HA, Suwon-si (KR)

(73) Assignee: Samsung Electronics Co., Ltd., Suwon-si (KR)

(21) Appl. No.: 18/537,546

(22) Filed: Dec. 12, 2023

(30) Foreign Application Priority Data
Jan. 27, 2023 (KR) 10-2023-0010869

(51) Int. Cl. H01L 29/417; H01L 23/528; H01L 27/088; H01L 29/06; H01L 29/423; H01L 29/775; H01L 29/786

(52) U.S. Cl. CPC H01L 29/4175; H01L 23/5286; H01L 27/088; H01L 29/0673; H01L 29/41775; H01L 29/42392; H01L 29/775; H01L 29/78696

(57) ABSTRACT

A semiconductor device includes an active pattern on a substrate, a source/drain pattern on the active pattern, a first metal layer on the source/drain pattern, the first metal layer comprising a power interconnection line, a through-via electrically connected to the power interconnection line, the through-via vertically extending to penetrate the substrate, a power delivery network layer on a bottom surface of the substrate, and a lower through-via between the power delivery network layer and the through-via. The through-via includes a first metal pattern connected to the lower through-via, and a second metal pattern stacked on the first metal pattern. A density of the first metal pattern is greater than a density of the second metal pattern. A resistivity of the first metal pattern is greater than a resistivity of the second metal pattern.

### CROSS-REFERENCE TO RELATED APPLICATIONS

This U.S. non-provisional patent application claims priority under 35 U.S.C. § 119 to Korean Patent Application No. 10-2023-0010869, filed on Jan. 27, 2023, in the Korean Intellectual Property Office, the entire contents of which are hereby incorporated by reference.

### BACKGROUND

The present disclosure relates to semiconductor devices and methods of manufacturing the same, and more particularly, to semiconductor devices including a field effect transistor and methods of manufacturing the same.

Semiconductor devices may include integrated circuits including metal-oxide-semiconductor field effect transistors (MOSFETs). As sizes and design rules of semiconductor devices have been reduced, MOSFETs have been scaled down. Operating characteristics of semiconductor devices may be deteriorated by reduction in size of MOSFETs. Accordingly, various methods for forming semiconductor devices which have excellent performance while overcoming limitations caused by high integration have been studied.

### SUMMARY

Some example embodiments of the inventive concepts may provide semiconductor devices with improved electrical characteristics and reliability.

Some example embodiments of the inventive concepts may also provide methods of manufacturing a semiconductor device with improved electrical characteristics and reliability.

According to an example embodiment, a semiconductor device may include an active pattern on a substrate, a source/drain pattern on the active pattern, a first metal layer on the source/drain pattern, the first metal layer comprising a power interconnection line, a through-via electrically connected to the power interconnection line, the through-via vertically extending to penetrate the substrate, a power delivery network layer on a bottom surface of the substrate, and a lower through-via between the power delivery network layer and the through-via. The through-via may include a first metal pattern connected to the lower through-via, and a second metal pattern stacked on the first metal pattern. A density of the first metal pattern may be greater than a density of the second metal pattern. A resistivity of the first metal pattern may be greater than a resistivity of the second metal pattern.

According to an example embodiment, a semiconductor device may include a plurality of power interconnection lines on a substrate, the power interconnection lines arranged in a first direction, and the power interconnection lines extending in a second direction in parallel to each other, a plurality of logic cells two-dimensionally arranged on the substrate, a plurality of tab cells arranged in the first direction on the substrate, and a power delivery network layer under the substrate. The plurality of tab cells may include a plurality of through-vias electrically connected to the plurality of power interconnection lines, respectively, and a plurality of lower through-vias electrically connecting the plurality of through-vias to the power delivery network layer, respectively. The power delivery network layer may be configured to apply voltages to the plurality of power interconnection lines through the through-vias and the lower through-vias. Each of the through-vias may include a first metal pattern being in contact with a corresponding one of the lower through-vias, and a second metal pattern stacked on the first metal pattern. A resistivity of the first metal pattern may be greater than a resistivity of the second metal pattern.

According to an example embodiment, a semiconductor device may include a first power interconnection line and a second power interconnection line on a substrate, the first and second power interconnection lines spaced apart from each other in a first direction, and the first and second power interconnection lines extending in a second direction in parallel to each other, a logic cell and a tab cell between the first and second power interconnection lines, the logic cell and the tab cell adjacent to each other in the second direction, a first active pattern and a second active pattern on the logic cell, the first and second active patterns spaced apart from each other in the first direction, a first channel pattern and a first source/drain pattern on the first active pattern, a second channel pattern and a second source/drain pattern on the second active pattern, the second source/drain pattern having a conductivity type different from that of the first source/drain pattern, a gate electrode on the first and second channel patterns, a gate insulating layer between the gate electrode and the first and second channel patterns, a gate spacer on a sidewall of the gate electrode, a gate capping pattern on a top surface of the gate electrode, an interlayer insulating layer covering the first and second source/drain patterns and the gate capping pattern, an active contact penetrating the interlayer insulating layer and electrically connected to at least one of the first and second source/drain patterns, a metal-semiconductor compound layer between the active contact and the at least one of the first and second source/drain patterns, a gate contact penetrating the interlayer insulating layer and the gate capping pattern and electrically connected to the gate electrode, a first through-via and a second through-via on the tab cell, the first and second through-vias electrically connected to the first and second power interconnection lines, respectively, a power delivery network layer on a bottom surface of the substrate, and a first lower through-via and a second lower through-via provided between the power delivery network layer and the first and second through-vias, respectively. Each of the first and second through-vias may include a first metal pattern being in contact with a corresponding one of the first and second lower through-vias, and a second metal pattern stacked on the first metal pattern. The first metal pattern and the second metal pattern may include different metals.

### BRIEF DESCRIPTION OF THE DRAWINGS

FIGS. 1 to 3 are conceptual views illustrating logic cells of a semiconductor device according to some example embodiments of the inventive concepts.

FIG. 4 is a plan view illustrating a semiconductor device according to an example embodiment of the inventive concepts.

FIGS. 5A, 5B, 5C, 5D, 5E and 5F are cross-sectional views taken along lines A-A′, B-B′, C-C′, D-D′, E-E′ and F-F′ of FIG. 4, respectively.

FIGS. 6A to 14 are cross-sectional views illustrating a method of manufacturing a semiconductor device according to an example embodiment of the inventive concepts.

FIGS. 15 and 16 are cross-sectional views taken along the line F-F′ of FIG. 4 to illustrate semiconductor devices according to some example embodiments of the inventive concepts.

FIGS. 17 and 18 are plan views illustrating arrangements of tab cells and logic cells of semiconductor devices according to some example embodiments of the inventive concepts.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

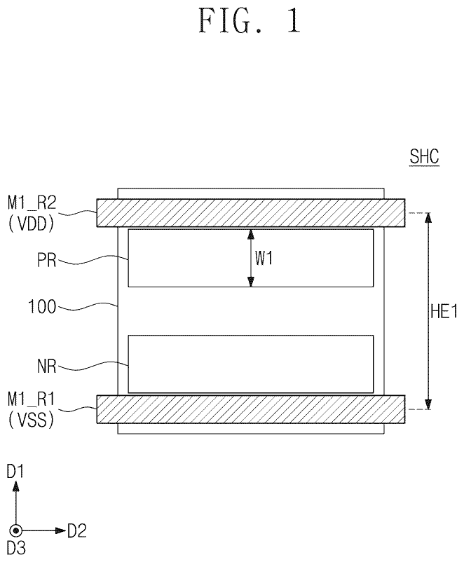

FIGS. 1 to 3 are conceptual views illustrating logic cells of a semiconductor device according to some example embodiments of the inventive concepts.

Referring to FIG. 1, a single height cell SHC may be provided. For example, a first power interconnection line M1_R1 and a second power interconnection line M1_R2 may be provided on a substrate 100. The first power interconnection line M1_R1 may be a path through which a source voltage VSS (e.g., a ground voltage) is provided. The second power interconnection line M1_R2 may be a path through which a drain voltage VDD (e.g., a power voltage) is provided.

The single height cell SHC may be defined between the first power interconnection line M1_R1 and the second power interconnection line M1_R2. The single height cell SHC may include a PMOSFET region PR and an NMOSFET region NR. In other words, the single height cell SHC may have a CMOS structure provided between the first power interconnection line M1_R1 and the second power interconnection line M1_R2.

Each of the PMOSFET region PR and the NMOSFET region NR may have a first width W1 in a first direction D1. A length of the single height cell SHC in the first direction D1 may be defined as a first height HE1. The first height HE1 may be substantially equal to a distance (e.g., a pitch) between the first power interconnection line M1_R1 and the second power interconnection line M1_R2.

The single height cell SHC may form a logic cell. In the present specification, the logic cell may mean a logic element (e.g., an AND element, an OR element, an XOR element, an XNOR element, an inverter, etc.) for performing a specific function. In other words, the logic cell may include transistors and interconnection lines connecting the transistors to each other, which constitute the logic element.

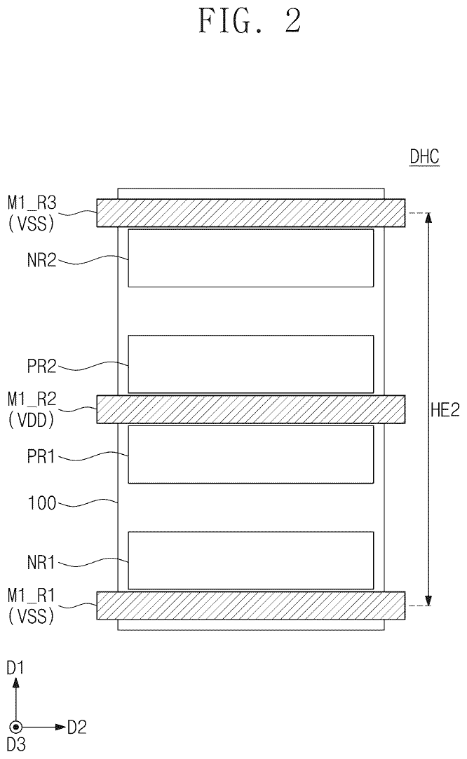

Referring to FIG. 2, a double height cell DHC may be provided. For example, a first power interconnection line M1_R1, a second power interconnection line M1_R2 and a third power interconnection line M1_R3 may be provided on a substrate 100. The second power interconnection line M1_R2 may be disposed between the first power interconnection line M1_R1 and the third power interconnection line M1_R3. The third power interconnection line M1_R3 may be a path through which a source voltage VSS is provided.

The double height cell DHC may be defined between the first power interconnection line M1_R1 and the third power interconnection line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the first power interconnection line M1_R1. The second NMOSFET region NR2 may be adjacent to the third power interconnection line M1_R3. The first and second PMOSFET regions PR1 and PR2 may be adjacent to the second power interconnection line M1_R2. The second power interconnection line M1_R2 may be disposed between the first and second PMOSFET regions PR1 and PR2 when viewed in a plan view.

A length of the double height cell DHC in the first direction D1 may be defined as a second height HE2. The second height HE2 may be about twice the first height HE1 of FIG. 1. The first and second PMOSFET regions PR1 and PR2 of the double height cell DHC may be combined with each other to operate as a single PMOSFET region. Thus, a size of a channel of a PMOS transistor of the double height cell DHC may be greater than a size of a channel of a PMOS transistor of the single height cell SHC described above in FIG. 1.

For example, the size of the channel of the PMOS transistor of the double height cell DHC may be about twice the size of the channel of the PMOS transistor of the single height cell SHC. Thus, the double height cell DHC may operate at a higher speed than the single height cell SHC. The double height cell DHC shown in FIG. 2 may be defined as a multi-height cell. Even though not shown in the drawings, in some example embodiments, the multi-height cell may include a triple height cell of which a cell height is about three times that of the single height cell SHC.

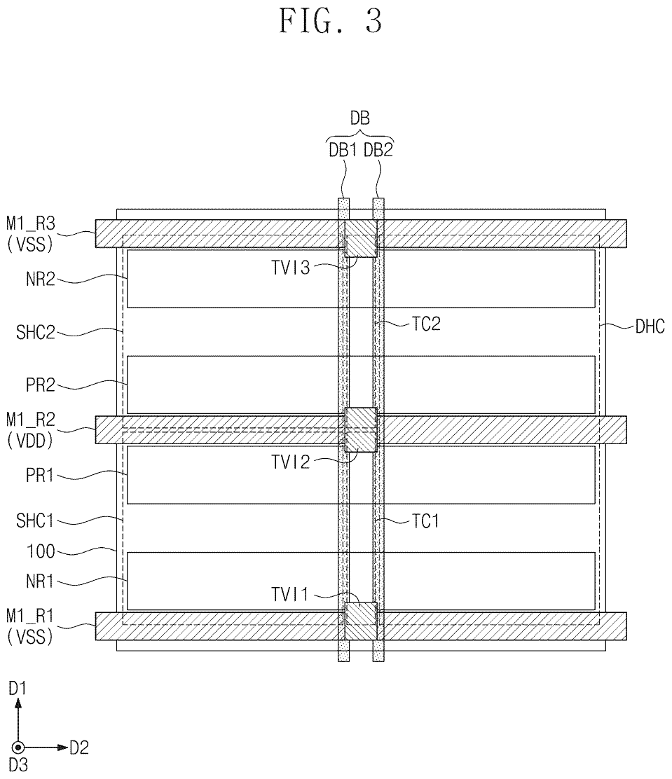

Referring to FIG. 3, a first single height cell SHC1, a second single height cell SHC2 and a double height cell DHC may be two-dimensionally disposed on a substrate 100. The first single height cell SHC1 may be disposed between the first and second power interconnection lines M1_R1 and M1_R2. The second single height cell SHC2 may be disposed between the second and third power interconnection lines M1_R2 and M1_R3. The second single height cell SHC2 may be adjacent to the first single height cell SHC1 in the first direction D1.

The double height cell DHC may be disposed between the first and third power interconnection lines M1_R1 and M1_R3. The double height cell DHC may be adjacent to the first and second single height cells SHC1 and SHC2 in a second direction D2.

A first tab cell TC1 may be provided between the first single height cell SHC1 and the double height cell DHC. A second tab cell TC2 may be provided between the second single height cell SHC2 and the double height cell DHC. The first tab cell TC1 and the second tab cell TC2 may be aligned with each other in the first direction D1.

Each of the first and second tab cells TC1 and TC2 may be a cell for applying a voltage from a power delivery network to be described later to at least one of the power interconnection lines M1_R1 to M1_R3. The tab cell may not include a logic element, unlike the logic cell. In other words, the tab cell may be a dummy cell which performs the function of applying a voltage to the power interconnection line but does not perform a circuit function.

As illustrated in FIG. 3, the first and second tab cells TC1, TC2 may be disposed between the logic cells SHC1, SHC2 and DHC in a cell region in which the logic cells SHC1, SHC2 and DHC are disposed. The arrangement of the first and second tab cells TC1 and TC2 and the logic cells SHC1, SHC2 and DHC in FIG. 3 is simply illustrated, but the arrangement of the logic cells and the tab cells may be variously changed.

In some embodiments of the inventive concepts, a first isolation structure DB1 may be provided between the first tab cell TC1 and the first single height cell SHC1 and between the second tab cell TC2 and the second single height cell SHC2. A second isolation structure DB2 may be provided between the first tab cell TC1 and the double height cell DHC and between the second tab cell TC2 and the double height cell DHC. Active regions of the logic cells SHC1, SHC2 and DHC may be electrically isolated from active regions of the tab cells TC1 and TC2 by an isolation structure DB including the first and second isolation structures DB1 and DB2.

The first and second tab cells TC1 and TC2 may include first to third through-vias TVI1, TVI2 and TVI3 connected to the first to third power interconnection lines M1_R1, M1_R2 and M1_R3, respectively. The first to third power interconnection lines M1_R1, M1_R2 and M1_R3 may be electrically connected to the power delivery network under the substrate 100 through the first to third through-vias TVI1, TVI2 and TVI3.

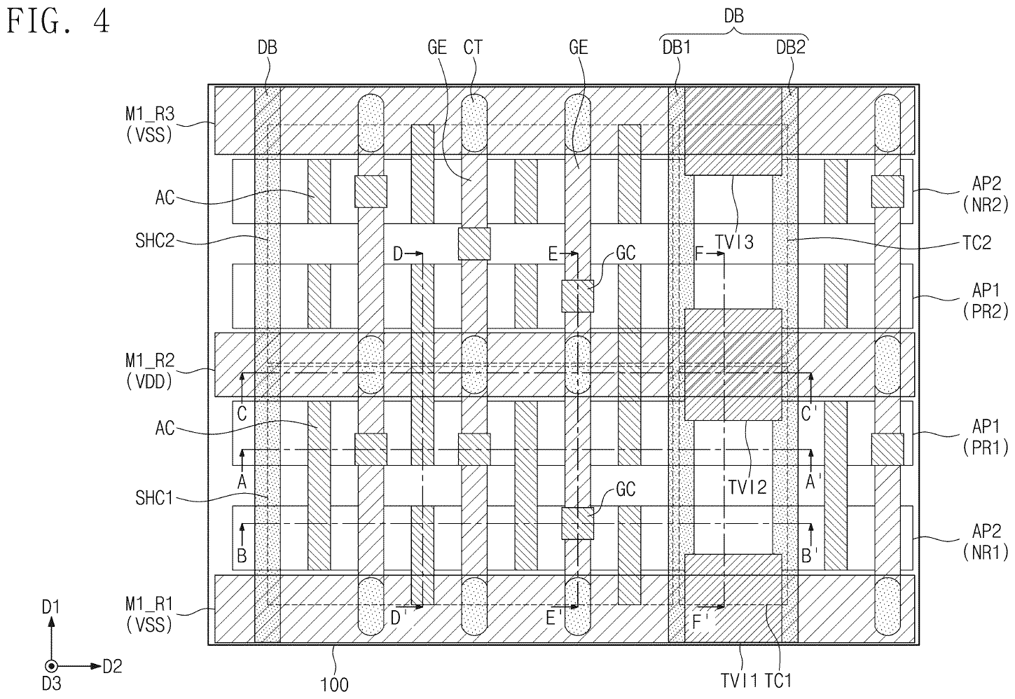

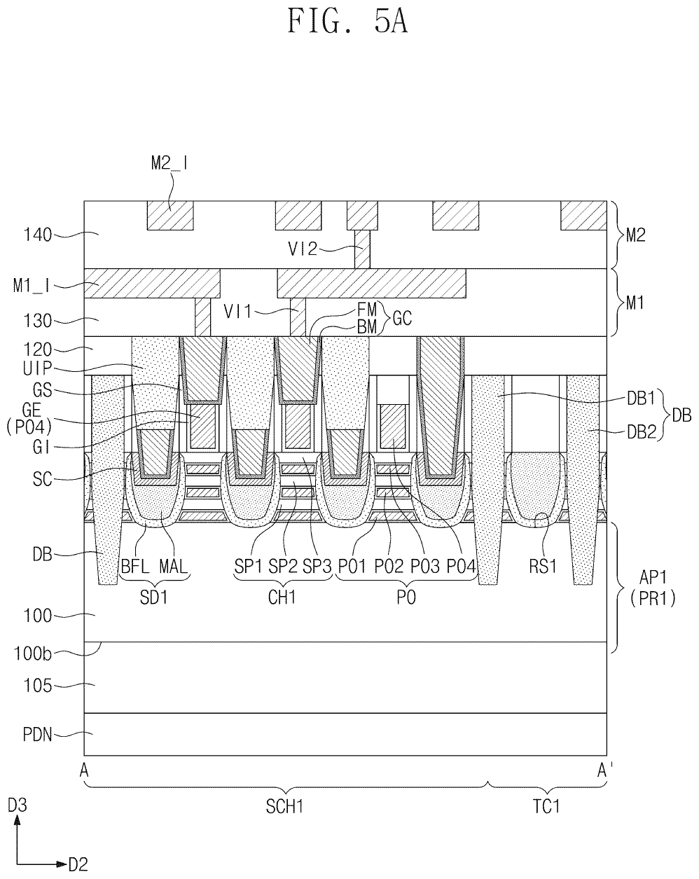

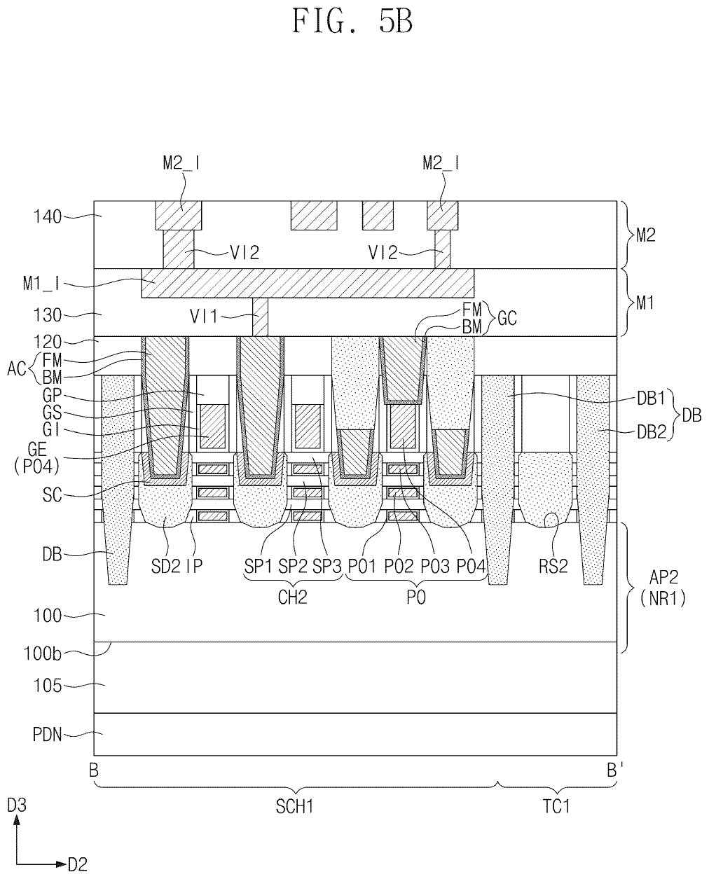

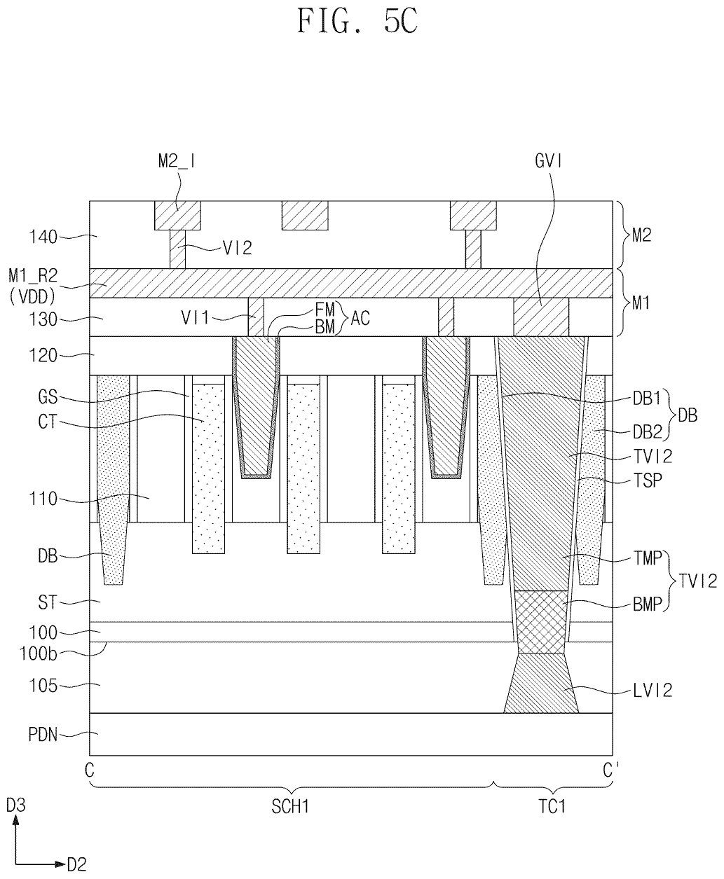

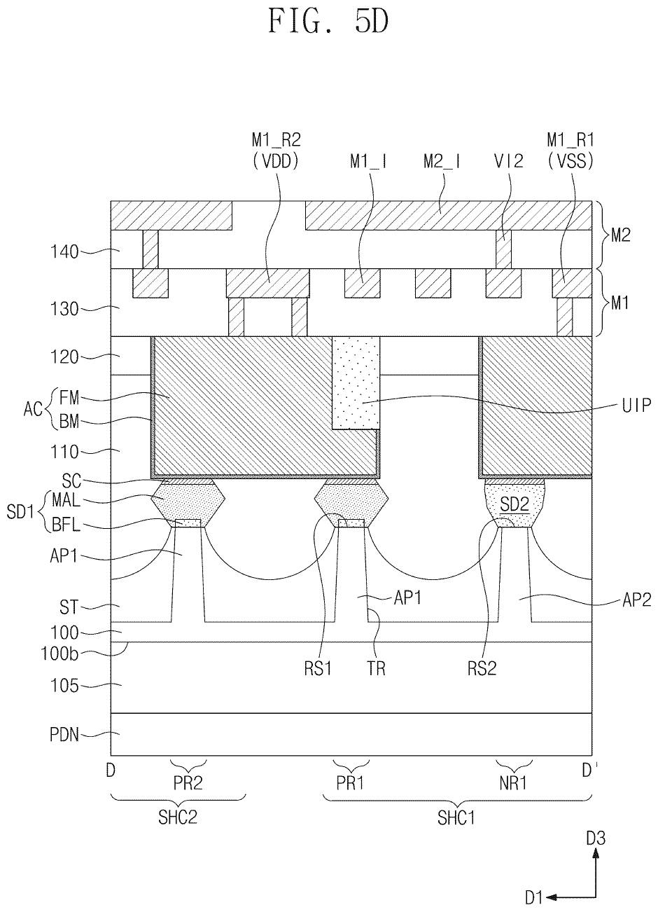

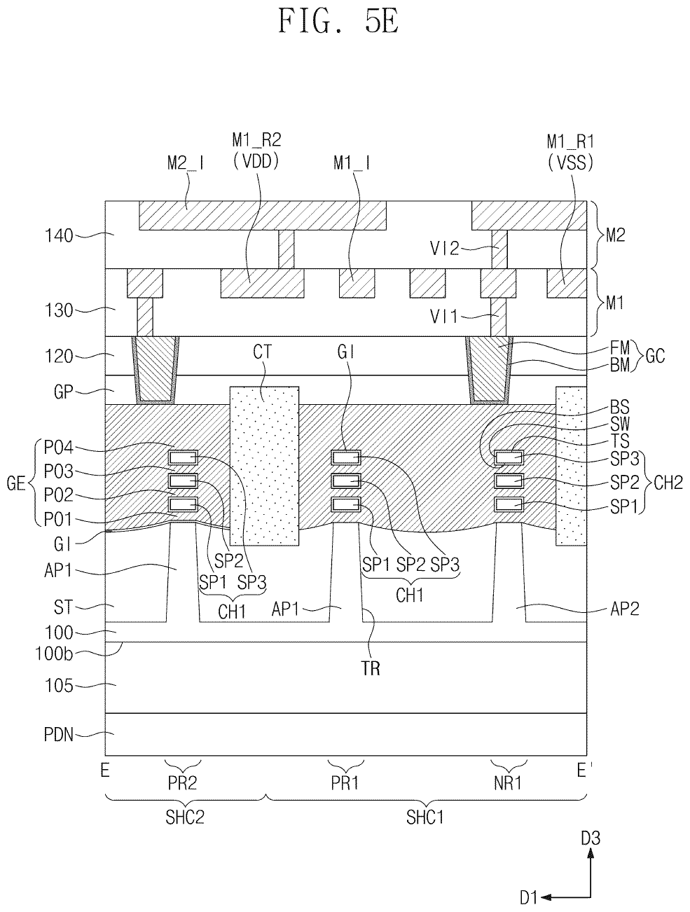

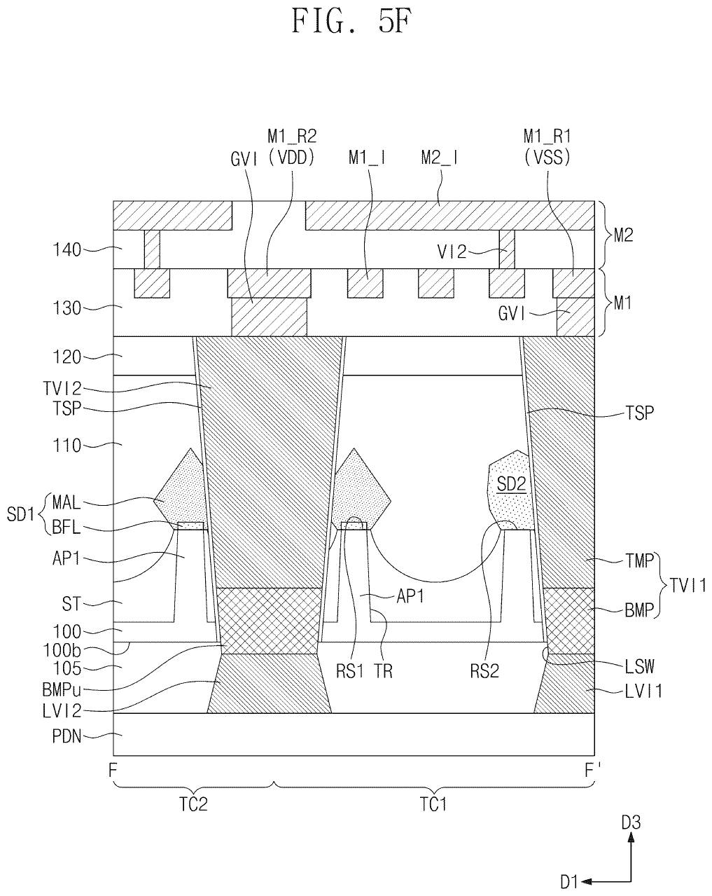

FIG. 4 is a plan view illustrating a semiconductor device according to an example embodiment of the inventive concepts. FIGS. 5A, 5B, 5C, 5D, 5E and 5F are cross-sectional views taken along lines A-A′, B-B′, C-C′, D-D′, E-E′ and F-F′ of FIG. 4, respectively. The semiconductor device shown in FIGS. 4 and 5A to 5F may correspond to a specific example embodiment of the first and second single height cells SHC1 and SHC2 and the first and second tab cells TC1 and TC2 of FIG. 3.

Referring to FIGS. 4 and 5A to 5F, first and second single height cells SHC1 and SHC2 and first and second tab cells TC1 and TC2 may be provided on a substrate 100. Logic transistors constituting a logic circuit may be disposed on each of the first and second single height cells SHC1 and SHC2. Dummy transistors may be disposed on each of the first and second tab cells TC1 and TC2. The substrate 100 may be a semiconductor substrate including silicon, germanium or silicon-germanium, or a compound semiconductor substrate. For example, the substrate 100 may be a silicon substrate.

The substrate 100 may have a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1 and the second NMOSFET region NR2 may extend in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR formed in an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may extend in the second direction D2. The first and second active patterns AP1 and AP2 may be portions of the substrate 100, which vertically protrude.

A device isolation layer ST may fill the trench TR. The device isolation layer ST may include a silicon oxide layer. The device isolation layer ST may not cover first and second channel patterns CH1 and CH2 to be described later.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2 and a third semiconductor pattern SP3, which are sequentially stacked. The first to third semiconductor patterns SP1, SP2 and SP3 may be spaced apart from each other in a vertical direction (i.e., a third direction D3).

Each of the first to third semiconductor patterns SP1, SP2 and SP3 may include silicon (Si), germanium (Ge), or silicon-germanium (SiGe). For example, each of the first to third semiconductor patterns SP1, SP2 and SP3 may include crystalline silicon. Each of the first to third semiconductor patterns SP1, SP2 and SP3 may be a nanosheet.

A plurality of first source/drain patterns SD1 may be provided on the first active pattern AP1. A plurality of first recesses RS1 may be formed on the first active pattern AP1. The first source/drain patterns SD1 may be provided in the first recesses RS1, respectively. The first source/drain patterns SD1 may be dopant regions having a first conductivity type (e.g., a p-type). The first channel pattern CH1 may be disposed between a pair of the first source/drain patterns SD1. In other words, the first to third semiconductor patterns SP1, SP2 and SP3 stacked sequentially may connect the pair of first source/drain patterns SD1 to each other.

A plurality of second source/drain patterns SD2 may be provided on the second active pattern AP2. A plurality of second recesses RS2 may be formed on the second active pattern AP2. The second source/drain patterns SD2 may be provided in the second recesses RS2, respectively. The second source/drain patterns SD2 may be dopant regions having a second conductivity type (e.g., an n-type). The second channel pattern CH2 may be disposed between a pair of the second source/drain patterns SD2. In other words, the first to third semiconductor patterns SP1, SP2 and SP3 stacked sequentially may connect the pair of second source/drain patterns SD2 to each other.

The first and second source/drain patterns SD1 and SD2 may be epitaxial patterns formed by a selective epitaxial growth (SEG) process. For example, a top surface of each of the first and second source/drain patterns SD1 and SD2 may be located at substantially the same level as a top surface of the third semiconductor pattern SP3. In some example embodiments, the top surface of each of the first and second source/drain patterns SD1 and SD2 may be higher than the top surface of the third semiconductor pattern SP3.

The first source/drain patterns SD1 may include a semiconductor element (e.g., SiGe) of which a lattice constant is greater than a lattice constant of a semiconductor element of the substrate 100. Thus, the pair of first source/drain patterns SD1 may provide compressive stress to the first channel pattern CH1 therebetween. The second source/drain patterns SD2 may include the same semiconductor element (e.g., Si) as the substrate 100.

Each of the first source/drain patterns SD1 may include a buffer layer BFL and a main layer MAL on the buffer layer BFL. Referring again to FIG. 5A, the buffer layer BFL may cover an inner surface of the first recess RS1. The buffer layer BFL may have a U-shape along a profile of the first recess RS1.

The main layer MAL may fill a remaining region of the first recess RS1 except the buffer layer BFL. A volume of the main layer MAL may be greater than a volume of the buffer layer BFL. Each of the buffer layer BFL and the main layer MAL may include silicon-germanium (SiGe). For example, the buffer layer BFL may contain a relatively low concentration of germanium (Ge). In certain example embodiments of the inventive concepts, the buffer layer BFL may contain silicon (Si) except germanium (Ge). A concentration of germanium (Ge) of the buffer layer BFL may range from 0 at % to 30 at %.

The main layer MAL may contain a relatively high concentration of germanium (Ge). For example, a concentration of germanium (Ge) of the main layer MAL may range from 30 at % to 70 at %. The concentration of germanium (Ge) of the main layer MAL may increase toward the third direction D3. For example, the main layer MAL adjacent to the buffer layer BFL may have a germanium (Ge) concentration of about 40 at %, and an upper portion of the main layer MAL may have a germanium (Ge) concentration of about 60 at %.

Each of the buffer layer BFL and the main layer MAL may include dopants (e.g., boron, gallium, or indium) for allowing the first source/drain pattern SD1 to have the p-type. A concentration of the dopants of each of the buffer layer BFL and the main layer MAL may range from 1E18 atom/cm³ to 5E22 atom/cm³. The concentration of the dopants of the main layer MAL may be greater than the concentration of the dopants of the buffer layer BFL.

The buffer layer BFL may mitigate or prevent a stacking fault between the substrate 100 (i.e., the first active pattern AP1) and the main layer MAL and between the main layer MAL and the first to third semiconductor patterns SP1, SP2 and SP3. When the stacking fault occurs, a channel resistance may be increased. The buffer layer BFL may protect the main layer MAL during a process of replacing second semiconductor layers SAL with first to third inner electrodes PO1, PO2 and PO3 of a gate electrode GE. In other words, the buffer layer BFL may block or prevent an etching material of removing the second semiconductor layers SAL from permeating to the main layer MAL to etch it.

Each of the second source/drain patterns SD2 may include silicon (Si). The second source/drain pattern SD2 may further include dopants (e.g., phosphorus, arsenic, or antimony) for allowing the second source/drain pattern SD2 to have the n-type. A concentration of the dopants of the second source/drain pattern SD2 may range from 1E18 atom/cm³ to 5E22 atom/cm³.

Gate electrodes GE may extend in the first direction D1 to intersect the first and second channel patterns CH1 and CH2. The gate electrodes GE may be arranged in the second direction D2 at a first pitch. Each of the gate electrodes GE may vertically overlap with a corresponding one of the first and second channel patterns CH1 and CH2.

The gate electrode GE may include a first inner electrode PO1 disposed between the active pattern AP1 or AP2 and the first semiconductor pattern SP1, a second inner electrode PO2 disposed between the first semiconductor pattern SP1 and the second semiconductor pattern SP2, a third inner electrode PO3 disposed between the second semiconductor pattern SP2 and the third semiconductor pattern SP3, and an outer electrode PO4 on the third semiconductor pattern SP3.

Referring again to FIG. 5E, the gate electrode GE may be provided on a top surface TS, a bottom surface BS and both sidewalls SW of each of the first to third semiconductor patterns SP1, SP2 and SP3. In other words, a transistor according to an example embodiment of the present inventive concepts may be a three-dimensional field effect transistor (e.g., a MBCFET or a GAAFET) in which the gate electrode GE three-dimensionally surrounds a channel.

Gate cutting patterns CT may be provided on a boundary between the first and second single height cells SHC1 and SHC2. The gate cutting patterns CT may be arranged along the boundary at the first pitch. The gate cutting patterns CT may overlap with the gate electrodes GE, respectively, when viewed in a plan view. The gate cutting patterns CT may include an insulating material such as silicon oxide, silicon nitride or a combination thereof.

The gate electrode GE on the first single height cell SHC1 may be separated from the gate electrode GE on the second single height cell SHC2 by the gate cutting pattern CT. The gate cutting pattern CT may be disposed between the gate electrode GE on the first single height cell SHC1 and the gate electrode GE on the second single height cell SHC2, which are aligned with each other in the first direction D1. In other words, the gate electrode GE extending in the first direction D1 may be divided into a plurality of the gate electrodes GE by the gate cutting patterns CT.

Referring again to FIGS. 4 and 5A to 5F, a pair of gate spacers GS may be disposed on both sidewalls of the outer electrode PO4 of the gate electrode GE, respectively. The gate spacers GS may extend along the gate electrode GE in the first direction D1. Top surfaces of the gate spacers GS may be higher than a top surface of the gate electrode GE. The top surfaces of the gate spacers GS may be coplanar with a top surface of a first interlayer insulating layer 110 to be described later. The gate spacers GS may include at least one of SiCN, SiCON, or SiN. For certain examples, each of the gate spacers GS may include a multi-layer formed of at least two of SiCN, SiCON, or SiN.

A gate capping pattern GP may be provided on the gate electrode GE. The gate capping pattern GP may extend along the gate electrode GE in the first direction D1. The gate capping pattern GP may include a material having an etch selectivity with respect to first and second interlayer insulating layers 110 and 120 to be described later. For example, the gate capping pattern GP may include at least one of SiON, SiCN, SiCON, or SiN.

A gate insulating layer GI may be disposed between the gate electrode GE and the first channel pattern CH1 and between the gate electrode GE and the second channel pattern CH2. The gate insulating layer GI may cover the top surface TS, the bottom surface BS and the both sidewalls SW of each of the first to third semiconductor patterns SP1, SP2 and SP3. The gate insulating layer GI may cover a top surface of the device isolation layer ST under the gate electrode GE.

In some example embodiments, the gate insulating layer GI may include a silicon oxide layer, a silicon oxynitride layer, and/or a high-k dielectric layer. The high-k dielectric layer may include a high-k dielectric material of which a dielectric constant is higher than that of a silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate electrode GE may include a first electrode pattern and a second electrode pattern on the first electrode pattern. The first electrode pattern may be provided on the gate insulating layer GI and may be adjacent to the first to third semiconductor patterns SP1, SP2 and SP3. The first electrode pattern may include a work function metal of adjusting a threshold voltage of a transistor. A desired threshold voltage of the transistor may be obtained by adjusting a thickness and a composition of the first electrode pattern. For example, the first to third inner electrodes PO1, PO2 and PO3 of the gate electrode GE may be formed of the first electrode pattern corresponding to the work function metal.

The first electrode pattern may include a metal nitride. For example, the first electrode pattern may include nitrogen (N) and at least one metal selected from a group consisting of titanium (Ti), tantalum (Ta), aluminum (Al), tungsten (W), and molybdenum (Mo). In addition, the first electrode pattern may further include carbon (C). In some example embodiments, the first electrode pattern may include a plurality of stacked work function metal layers.

The second electrode pattern may include a metal having a resistance lower than that of the first electrode pattern. For example, the second electrode pattern may include at least one metal selected from a group consisting of tungsten (W), aluminum (Al), titanium (Ti), and tantalum (Ta). For example, the outer electrode PO4 of the gate electrode GE may include the first electrode pattern and the second electrode pattern on the first electrode pattern.

Referring again to FIG. 5B, inner spacers IP may be provided on the first and second NMOSFET regions NR1 and NR2. In other words, the inner spacers IP may be provided on the second active pattern AP2. The inner spacers IP may be disposed between the second source/drain pattern SD2 and the first to third inner electrodes PO1, PO2 and PO3 of the gate electrode GE, respectively. The inner spacers IP may be in direct contact with the second source/drain pattern SD2. Each of the first to third inner electrodes PO1, PO2 and PO3 of the gate electrode GE may be spaced apart from the second source/drain pattern SD2 by the inner spacer IP.

A first interlayer insulating layer 110 may be provided on the substrate 100. The first interlayer insulating layer 110 may cover the gate spacers GS and the first and second source/drain patterns SD1 and SD2. A top surface of the first interlayer insulating layer 110 may be substantially coplanar with the top surface of the gate capping pattern GP and the top surface of the gate spacer GS. A second interlayer insulating layer 120 covering the gate capping pattern GP may be disposed on the first interlayer insulating layer 110. A third interlayer insulating layer 130 may be provided on the second interlayer insulating layer 120. A fourth interlayer insulating layer 140 may be provided on the third interlayer insulating layer 130. For example, each of the first to fourth interlayer insulating layers 110 to 140 may include a silicon oxide layer.

Isolation structures DB may be provided at boundaries between the cells, respectively. For example, a first isolation structure DB1 may be provided between the first and second single height cells SHC1 and SHC2 and the first and second tab cells TC1 and TC2. A second isolation structure DB2 may be provided between the first and second tab cells TC1 and TC2 and another logic cell adjacent thereto. Each of the first and second tab cells TC1 and TC2 may be provided between a pair of the isolation structures DB1 and DB2.

The isolation structure DB may extend in the first direction D1 in parallel to the gate electrodes GE. A pitch between the isolation structure DB and the gate electrode GE adjacent thereto may be equal to the first pitch. In some example embodiments of the inventive concepts, a width, in the second direction D2, of each of the first and second tab cells TC1 and TC2 may be substantially equal to the first pitch.

The isolation structure DB may penetrate the gate capping pattern GP and the gate electrode GE and may extend into the first and second active patterns AP1 and AP2. The isolation structure DB may penetrate an upper portion of each of the first and second active patterns AP1 and AP2. The isolation structure DB may electrically isolate an active region of one cell from an active region of another cell adjacent thereto.

Active contacts AC may penetrate the first and second interlayer insulating layers 110 and 120 so as to be electrically connected to the first and second source/drain patterns SD1 and SD2. A pair of the active contacts AC may be provided at both sides of the gate electrode GE, respectively. The active contact AC may have a bar shape extending in the first direction D1 when viewed in a plan view.

The active contact AC may be a self-aligned contact. In other words, the active contact AC may be formed to be self-aligned with the gate capping pattern GP and the gate spacer GS. For example, the active contact AC may cover at least a portion of a sidewall of the gate spacer GS. Even though not shown in the drawings, the active contact AC may cover a portion of the top surface of the gate capping pattern GP.

Metal-semiconductor compound layers SC (e.g., silicide layers) may be disposed between the active contact AC and the first source/drain pattern SD1 and between the active contact AC and the second source/drain pattern SD2, respectively. The active contact AC may be electrically connected to the source/drain pattern SD1 or SD2 through the metal-semiconductor compound layer SC. For example, the metal-semiconductor compound layer SC may include at least one of titanium silicide, tantalum silicide, tungsten silicide, nickel silicide, or cobalt silicide.

Gate contacts GC may penetrate the second interlayer insulating layer 120 and the gate capping patterns GP so as to be electrically connected to the gate electrodes GE, respectively. Two gate contacts GC on the first single height cell SHC1 may overlap with the first PMOSFET region PR1 when viewed in a plan view. In other words, the two gate contacts GC on the first single height cell SHC1 may be provided on the first active pattern AP1 (see FIG. 5A). One gate contact GC on the first single height cell SHC1 may overlap with the first NMOSFET region NR1 when viewed in a plan view. In other words, the one gate contact GC on the first single height cell SHC1 may be provided on the second active pattern AP2 (see FIG. 5B).

The gate contact GC may be freely disposed on the gate electrode GE regardless of its position. For example, the gate contacts GC on the second single height cell SHC2 may be disposed on the second PMOSFET region PR2, the second NMOSFET region NR2 and the device isolation layer ST filling the trench TR, respectively (see FIG. 4).

In some example embodiments of the inventive concepts, referring to FIGS. 5A and 5D, an upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be lower than the bottom surface of the gate contact GC due to the upper insulating pattern UIP. Thus, it is possible to block or prevent an electrical short between the gate contact GC and the active contact AC adjacent thereto.

Each of the active contact AC and the gate contact GC may include a conductive pattern FM and a barrier pattern BM surrounding the conductive pattern FM. For example, the conductive pattern FM may include at least one metal of aluminum, copper, tungsten, molybdenum, or cobalt. The barrier pattern BM may cover sidewalls and a bottom surface of the conductive pattern FM. The barrier pattern BM may include a metal layer/a metal nitride layer. The metal layer may include at least one of titanium, tantalum, tungsten, nickel, cobalt, or platinum. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, or a platinum nitride (PtN) layer.

Referring again to FIGS. 4, 5C and 5F, a first metal layer M1 may be provided in the third interlayer insulating layer 130. The first metal layer M1 may include first to third power interconnection lines M1_R1, M1_R2 and M1_R3.

The first to third power interconnection lines M1_R1, M1_R2 and M1_R3 may extend parallel to each other in the second direction D2. The first power interconnection line M1_R1 may be disposed on a boundary of the first single height cell SHC1. The second power interconnection line M1_R2 may be disposed on a boundary between the first and second single height cells SHC1 and SHC2. The third power interconnection line M1_R3 may be disposed on a boundary of the second single height cell SHC2.

Referring again to FIGS. 5C and 5D, the second power interconnection line M1_R2 may be electrically connected to at least one of the active contacts AC. A first via VI1 may be provided between the second power interconnection line M1_R2 and the at least one active contact AC.

Referring again to FIGS. 4, 5C and 5F, first to third through-vias TVI1, TVI2 and TVI3 may be provided in the first and second tab cells TC1 and TC2. The first to third through-vias TVI1, TVI2 and TVI3 may be electrically connected to the first to third power interconnection lines M1_R1, M1_R2 and M1_R3, respectively.

The second through-via TVI2 may vertically extend from the second interlayer insulating layer 120 to a bottom surface 100b of the substrate 100. A top surface of the second through-via TVI2 may be coplanar with a top surface of the second interlayer insulating layer 120. In some example embodiments of the inventive concepts, a bottom surface of the second through-via TVI2 may be lower than the bottom surface 100b of the substrate 100. A giant via GVI may be provided between the second through-via TVI2 and the second power interconnection line M1_R2. The second through-via TVI2 and the second power interconnection line M1_R2 may be electrically connected to each other through the giant via GVI.

A lower insulating layer 105 may be provided on the bottom surface 100b of the substrate 100. First to third lower through-vias LVI1, LVI2 and LVI3 may be provided in the lower insulating layer 105. The first to third lower through-vias LVI1, LVI2 and LVI3 may be connected to the first to third through-vias TVI1, TVI2 and TVI3, respectively. The first to third lower through-vias LVI1, LVI2 and LVI3 may vertically overlap with the first to third through-vias TVI1, TVI2 and TVI3, respectively.

A power delivery network layer PDN may be provided under the lower insulating layer 105. The power delivery network layer PDN may include a plurality of lower interconnection lines electrically connected to the first to third lower through-vias LVI1, LVI2 and LVI3. In other words, the power delivery network layer PDN may be electrically connected to the first to third power interconnection lines M1_R1, M1_R2 and M1_R3.

For example, the power delivery network layer PDN may include an interconnection network for applying a source voltage VSS to the first and third power interconnection lines M1_R1 and M1_R3. The power delivery network layer PDN may include an interconnection network for applying a drain voltage VDD to the second power interconnection line M1_R2.

According to some example embodiments of the inventive concepts, each of the through-vias TVI1 to TVI3 may include a first metal pattern BMP and a second metal pattern TMP. The second metal pattern TMP may be stacked on the first metal pattern BMP. The first metal pattern BMP may be in direct contact with a corresponding one of the lower through-vias LVI1 to LVI3. The second metal pattern TMP may be spaced apart from the corresponding one of the lower through-vias LVI1 to LVI3.

In some example embodiments of the inventive concepts, a bottom surface of the first metal pattern BMP may be lower than the bottom surface 100b of the substrate 100. A bottom surface of the second metal pattern TMP may be higher than the bottom surface 100b of the substrate 100. A lower portion of the first metal pattern BMP may protrude from the bottom surface 100b of the substrate 100 and may be buried in the lower insulating layer 105.

The first metal pattern BMP and the second metal pattern TMP may include different metals. The first metal pattern BMP may include one of metals robust in a cleaning process and an etching process of an insulating layer. The first metal pattern BMP may include a noble metal or a rare earth metal. For example, the first metal pattern BMP may include at least one selected from a group consisting of silver (Ag), gold (Au), platinum (Pt), copper (Cu), iridium (Ir), ruthenium (Ru), scandium (Sc), yttrium (Y), and lanthanum (La).

The second metal pattern TMP may include a metal having a resistance lower than that of the first metal pattern BMP. For example, the second metal pattern TMP may include at least one selected from a group consisting of tungsten (W), molybdenum (Mo), ruthenium (Ru), aluminum (Al), titanium (Ti), and tantalum (Ta).

The first metal pattern BMP may be denser than the second metal pattern TMP. A density of the first metal pattern BMP may be greater than that of the second metal pattern TMP. A resistivity of the first metal pattern BMP may be greater than that of the second metal pattern TMP. In each of the through-vias TVI1 to TVI3, a volume occupied by the second metal pattern TMP may be greater than a volume occupied by the first metal pattern BMP.

The first metal pattern BMP may be resistant to a wet strip. For example, an etch resistance of the first metal pattern BMP to dilute hydrofluoric acid (DHF) or diluted sulfate peroxide (DSP) may be greater than an etch resistance of the second metal pattern TMP to the dilute hydrofluoric acid (DHF) or the diluted sulfate peroxide (DSP). Here, ‘the greater etch resistance’ may mean a smaller etch rate. The dilute hydrofluoric acid (DHF) or the diluted sulfate peroxide (DSP) may be a cleaning solution used in a semiconductor cleaning process.

According to some example embodiments of the inventive concepts, in a process of forming the through-vias TVI1 to TVI3 and the lower through-vias LVI1 to LVI3, the first metal patterns BMP formed of the robust metal may be provided in portions which may be easily damaged by cleaning and etching processes. Thus, it is possible to mitigate or prevent defects which may occur by the cleaning and etching processes. Meanwhile, a most portion of each of the through-vias TVI1 to TVI3 may be formed of the second metal pattern TMP having the low resistance, and thus the resistivity of the through-vias TVI1 to TVI3 may be lowered. Thus, reliability and electrical characteristics of the semiconductor device may be improved.

Each of the lower through-vias LVI1 to LVI3 may vertically extend from the power delivery network layer PDN to the bottom surface of each of the through-vias TVI1 to TVI3 (e.g., the bottom surface of the first metal pattern BMP). A top surface of each of the lower through-vias LVI1 to LVI3 may be in direct contact with the bottom surface of the first metal pattern BMP. The top surface of each of the lower through-vias LVI1 to LVI3 may be lower than the bottom surface 100b of the substrate 100.

In some example embodiments of the inventive concepts, the lower through-vias LVI1 to LVI3 may include the same metal as the second metal pattern TMP. For example, the second metal pattern TMP and the lower through-vias LVI1 to LVI3 may include tungsten (W).

In certain example embodiments of the inventive concepts, the lower through-vias LVI1 to LVI3 may include a different metal from that of the second metal pattern TMP. For example, the second metal pattern TMP may include tungsten (W), and the lower through-vias LVI1 to LVI3 may include copper.

Each of the through-vias TVI1 to TVI3 may be aligned with a corresponding one of the lower through-vias LVI1 to LVI3. In other words, a center line of each of the through-vias TVI1 to TVI3 may be aligned with a center line of the corresponding one of the lower through-vias LVI1 to LVI3.

A width (or diameter) of each of the through-vias TVI1 to TVI3 may increase toward the third direction D3. In other words, the width of each of the through-vias TVI1 to TVI3 may become progressively less toward the power delivery network layer PDN. A width (or diameter) of each of the lower through-vias LVI1 to LVI3 may become progressively greater toward the power delivery network layer PDN. Thus, each of the through-vias TVI1 to TVI3 and each of the lower through-vias LVI1 to LVI3, which correspond to each other, may be connected to each other to constitute a sandglass shape.

An upper spacer TSP may be provided on a sidewall of each of the through-vias TVI1 to TVI3. The upper spacer TSP may include a silicon-based insulating material (e.g., silicon oxide, silicon nitride, or silicon oxynitride).

Referring again to FIGS. 4 and 5A to 5F, the first metal layer M1 may further include first interconnection lines M1_I. The first interconnection lines M1_I may extend parallel to each other in the second direction D2.

The first metal layer M1 may further include first vias VI1. The first vias VI1 may be provided under the first interconnection lines M1_I of the first metal layer M1. The active contact AC and a corresponding one of the first interconnection lines M1_I may be electrically connected to each other through a corresponding one of the first vias VI1. The gate contact GC and a corresponding one of the first interconnection lines M1_I may be electrically connected to each other through a corresponding one of the first vias VI1.

The first interconnection line M1_I of the first metal layer M1 and the first via VI1 thereunder may be formed using different processes. In other words, each of the first interconnection line M1_I and the first via VI1 of the first metal layer M1 may be formed using a single damascene process. The semiconductor device according to the present example embodiments may be formed using processes less than 20 nm.

A second metal layer M2 may be provided in the fourth interlayer insulating layer 140. The second metal layer M2 may include a plurality of second interconnection lines M2_I. Each of the second interconnection lines M2_I of the second metal layer M2 may have a line shape or bar shape extending in the first direction D1. In other words, the second interconnection lines M2_I may extend in the first direction D1 in parallel to each other.

The second metal layer M2 may further include second vias VI2 provided under the second interconnection lines M2_I. The first interconnection line M1_I of the first metal layer M1 may be electrically connected to a corresponding one of the second interconnection lines M2_I of the second metal layer M2 through a corresponding one of the second vias VI2. For example, the second interconnection line M2_I of the second metal layer M2 and the second via VI2 thereunder may be formed using a dual damascene process together.

The first interconnection line M1_I of the first metal layer M1 and the second interconnection line M2_I of the second metal layer M2 may include the same conductive material or different conductive materials. For example, each of the first and second interconnection lines M1_I and M2_I of the first and second metal layers M1 and M2 may include at least one metal material of aluminum, copper, tungsten, molybdenum, ruthenium, or cobalt. Even though not shown in the drawings, metal layers (e.g., M3, M4, M5, . . . ) stacked on the fourth interlayer insulating layer 140 may be additionally provided. Each of the stacked metal layers may include interconnection lines for routing between cells.

The through-via TVI1, TIV2 or TVI3 and the lower through-via LVI1, LVI2 or LVI3 according to some example embodiments of the inventive concepts may be individually formed by different processes. In other words, a vertical contact extending from the power delivery network layer PDN to the first metal layer M1 may be divided into two portions (e.g., the through-via TVI1, TIV2 or TVI3 and the lower through-via LVI1, LVI2 or LVI3), and the two portions may be formed independently of each other. Thus, according to some example embodiments of the inventive concepts, the vertical contact TVI and LVI having a great aspect ratio may be easily filled with the metal, and thus reliability of the semiconductor device may be improved.

The vertical contact TVI and LVI according to some example embodiments of the inventive concepts may be divided into the through-via TVI and the lower through-via LVI, and the through-via TVI and the lower through-via LVI may be formed from a front surface and a back surface of the substrate 100, respectively. Thus, an area desired to form the vertical contact may be reduced. Thus, a size of the tab cell may be reduced, as described below.

Each of the tab cells TC1 and TC2 according to some example embodiments of the inventive concepts may have a size of the first pitch corresponding to the distance between the gate electrodes GE. In other words, each of the tab cells TC1 and TC2 according to some example embodiments of the inventive concepts may have a very small size. Because the sizes of the tab cells TC1 and TC2 are reduced, an area in which the logic cells are disposed may be increased in a logic die. Thus, an integration density of the semiconductor device may be improved.

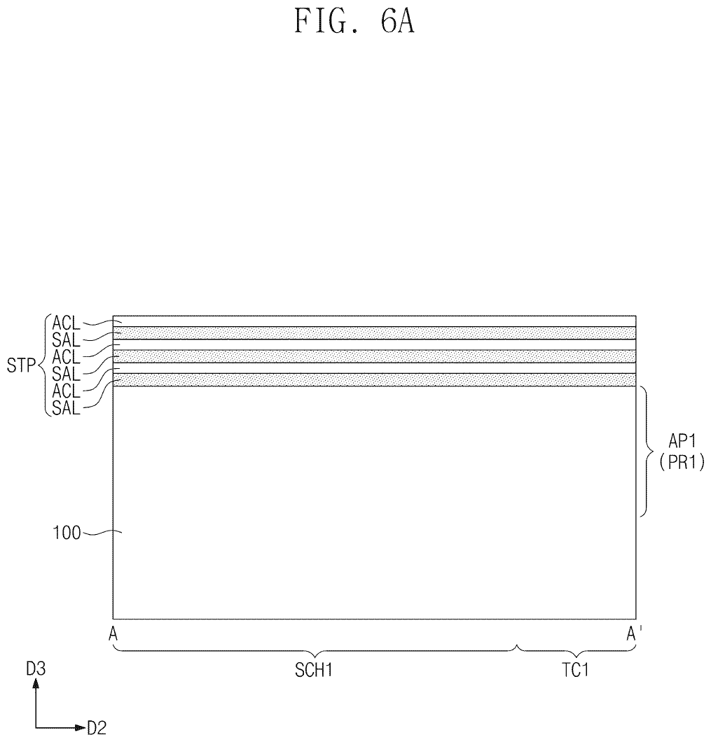

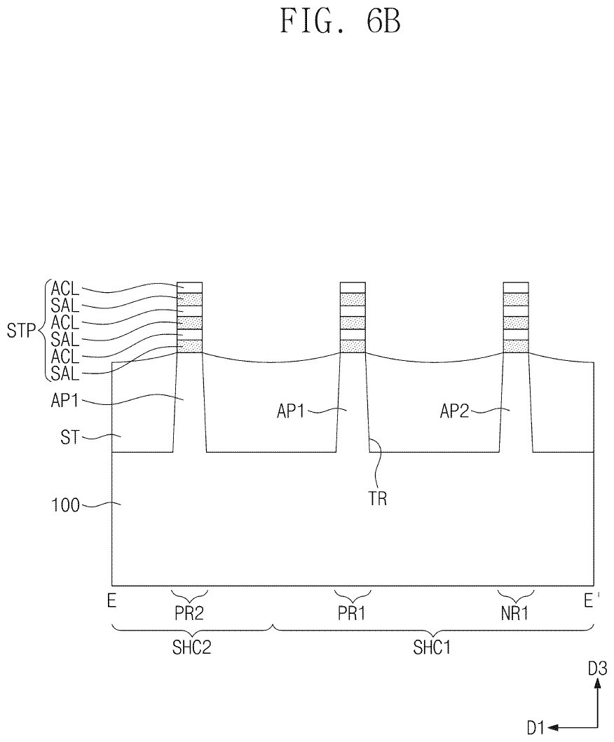

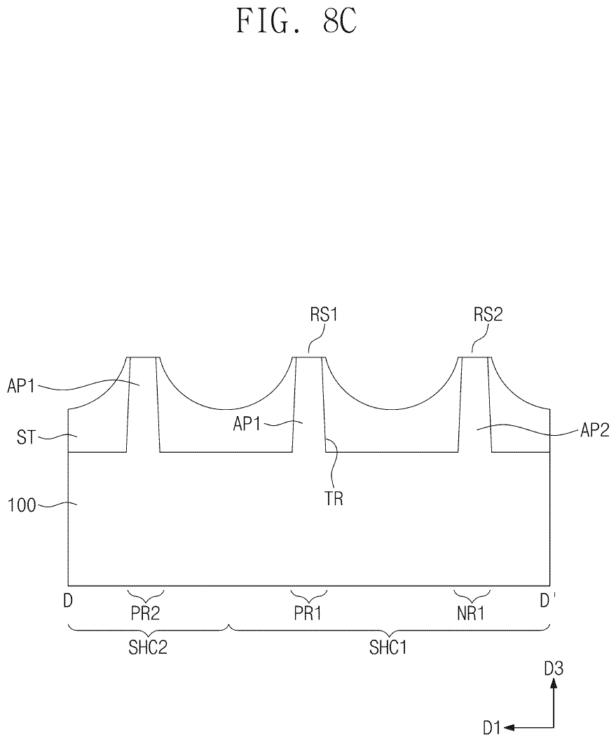

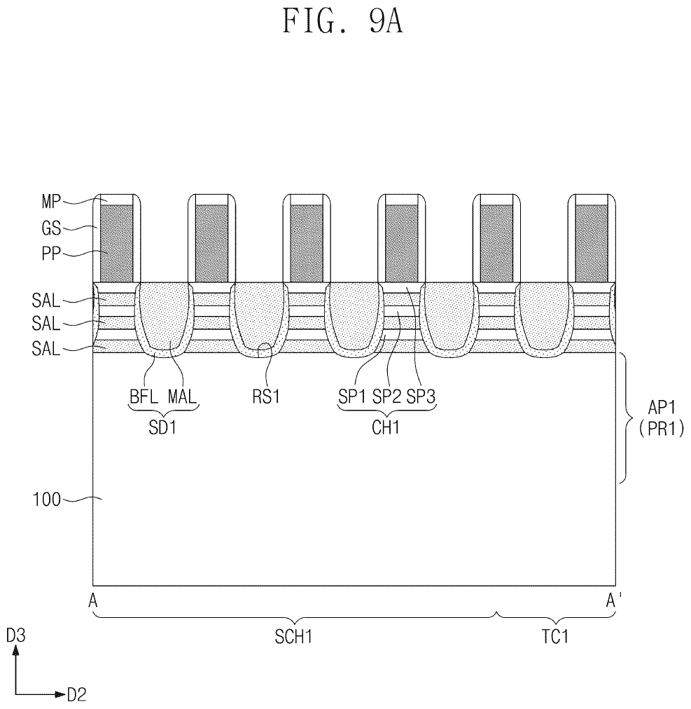

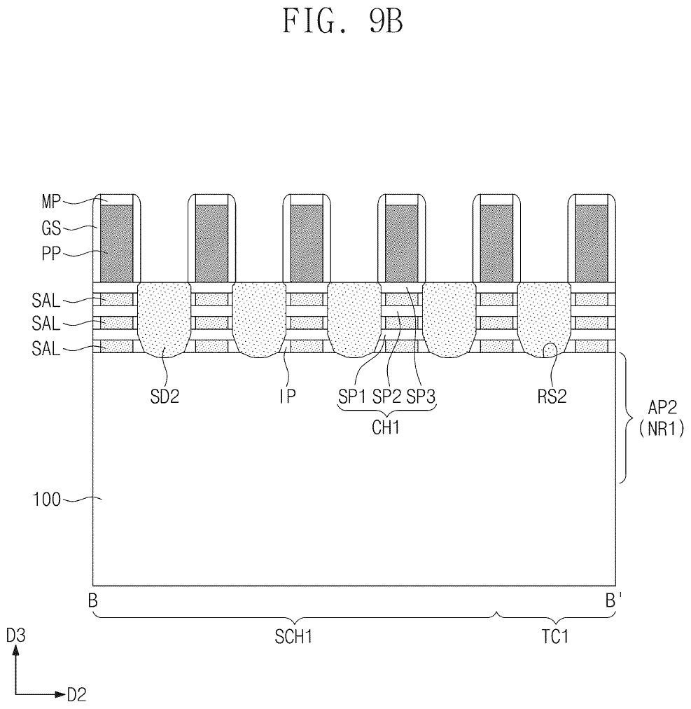

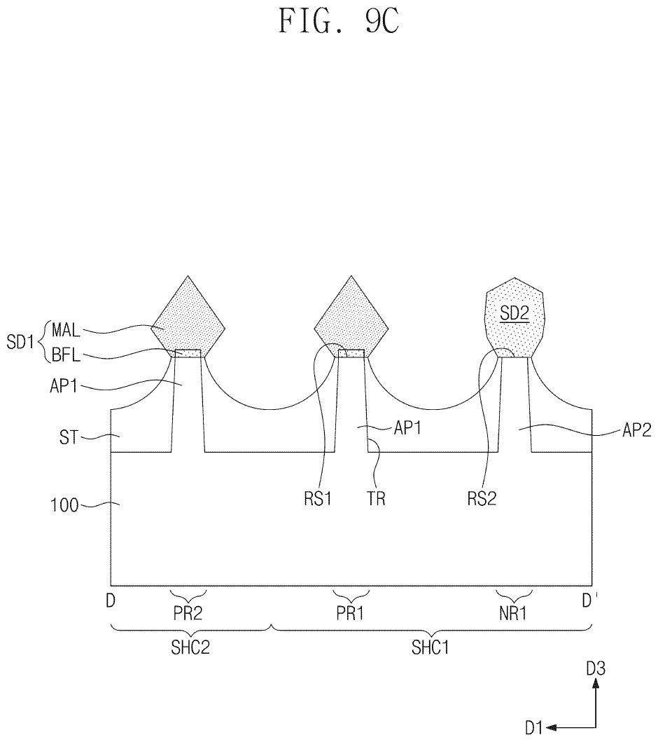

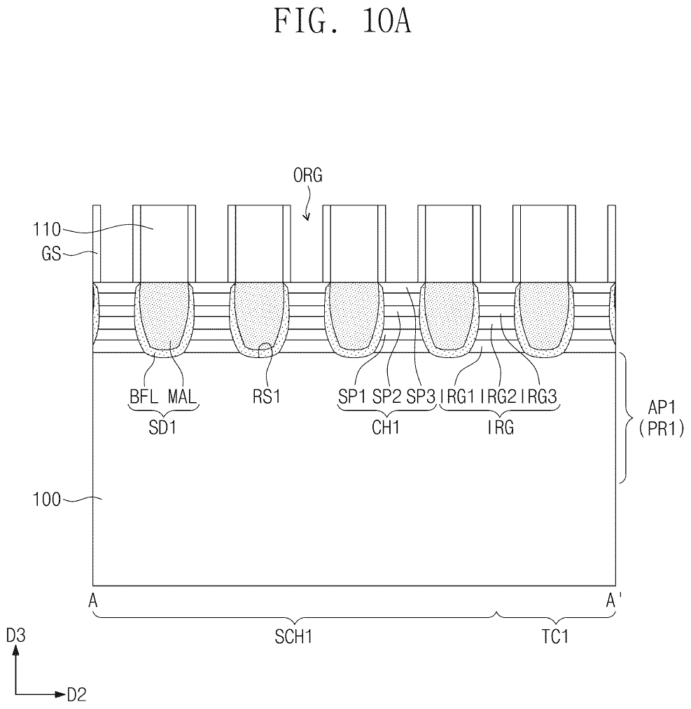

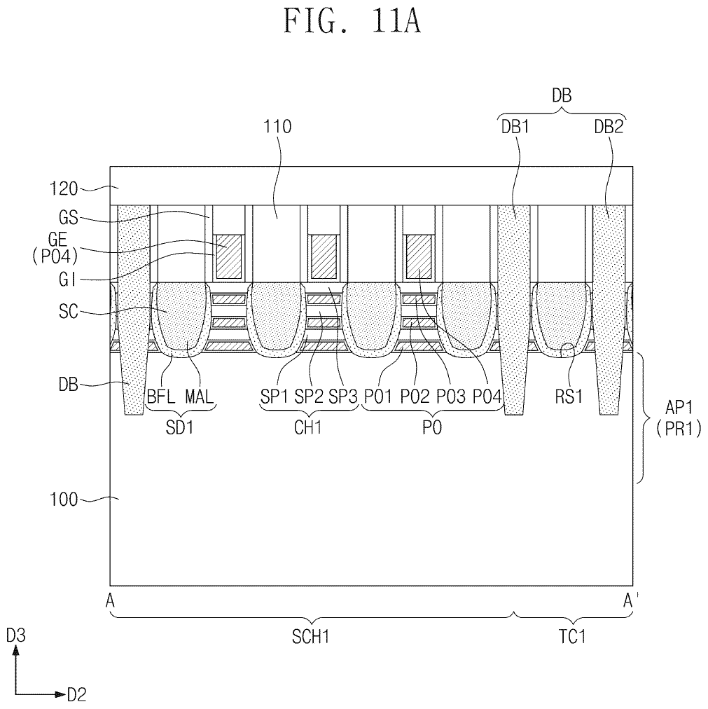

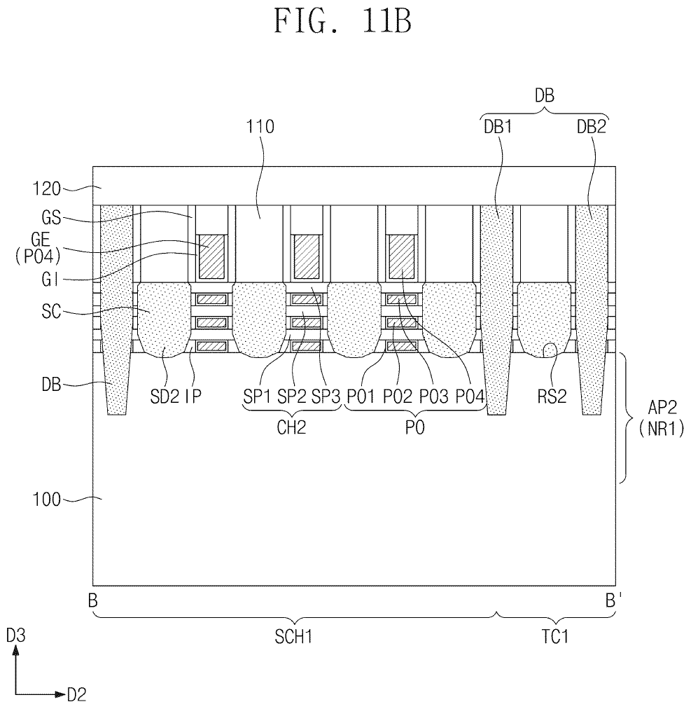

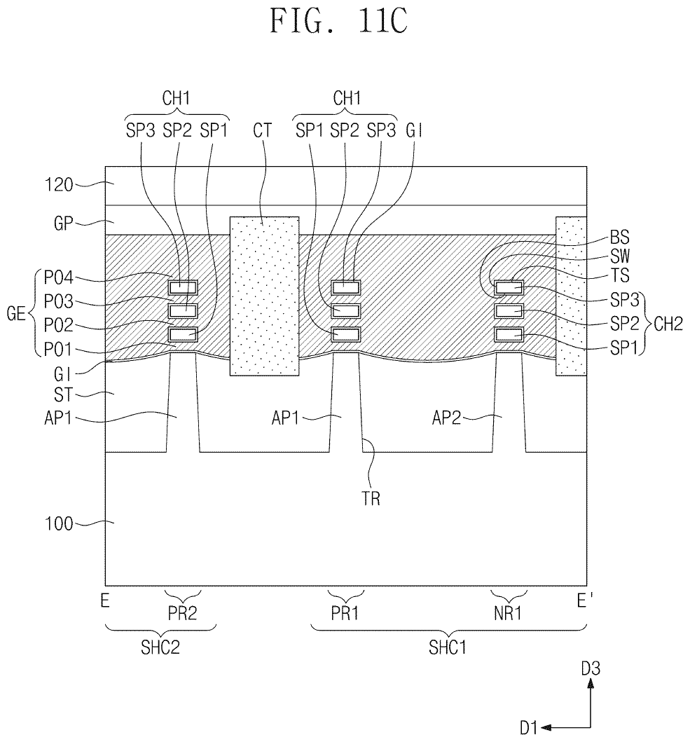

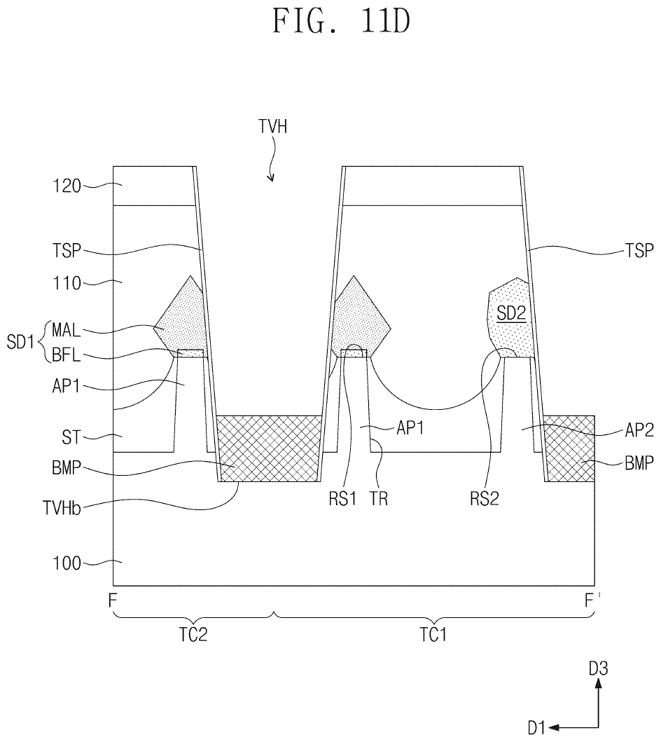

FIGS. 6A to 14 are cross-sectional views illustrating a method of manufacturing a semiconductor device according to an example embodiment of the inventive concepts. More particularly, FIGS. 6A, 7A, 8A, 9A, 10A and 11A are cross-sectional views corresponding to the line A-A′ of FIG. 4. FIGS. 8B, 9B, 10B and 11B are cross-sectional views corresponding to the line B-B′ of FIG. 4. FIGS. 8C and 9C are cross-sectional views corresponding to the line D-D′ of FIG. 4. FIGS. 6B, 7B, 10C and 11C are cross-sectional views corresponding to the line E-E′ of FIG. 4. FIGS. 11D, 12, 13 and 14 are cross-sectional views corresponding to the line F-F′ of FIG. 4.

Referring to FIGS. 6A and 6B, a substrate 100 including first and second PMOSFET regions PR1 and PR2 and first and second NMOSFET regions NR1 and NR2 may be provided. First semiconductor layers ACL and second semiconductor layers SAL may be alternately formed on the substrate 100. The first semiconductor layers ACL may include one of silicon (Si), germanium (Ge) and silicon-germanium (SiGe), and the second semiconductor layers SAL may include another of silicon (Si), germanium (Ge) and silicon-germanium (SiGe).

The second semiconductor layer SAL may include a material having an etch selectivity with respect to the first semiconductor layer ACL. For example, the first semiconductor layers ACL may include silicon (Si), and the second semiconductor layers SAL may include silicon-germanium (SiGe). A concentration of germanium (Ge) of each of the second semiconductor layers SAL may range from 10 at % to 30 at %.

Mask patterns may be formed on the first and second PMOSFET regions PR1 and PR2 and the first and second NMOSFET regions NR1 and NR2 of the substrate 100, respectively. Each of the mask patterns may have a line shape or bar shape extending in the second direction D2.

A patterning process may be performed using the mask patterns as etch masks to form a trench TR defining a first active pattern AP1 and a second active pattern AP2. The first active pattern AP1 may be formed on each of the first and second PMOSFET regions PR1 and PR2. The second active pattern AP2 may be formed on each of the first and second NMOSFET regions NR1 and NR2. The first and second active patterns AP1 and AP2 may have line shapes extending in the second direction D2 in parallel to each other when viewed in a plan view.

A stack pattern STP may be formed on each of the first and second active patterns AP1 and AP2. The stack pattern STP may include the first semiconductor layers ACL and the second semiconductor layers SAL, which are alternately stacked. The stack patterns STP may be formed together with the first and second active patterns AP1 and AP2 in the patterning process.

A device isolation layer ST filling the trench TR may be formed. For example, an insulating layer covering the first and second active patterns AP1 and AP2 and the stack patterns STP may be formed on an entire top surface of the substrate 100. The insulating layer may be recessed until the stack patterns STP are exposed, thereby forming the device isolation layer ST.

The device isolation layer ST may include an insulating material (e.g., silicon oxide). The stack patterns STP may be exposed above the device isolation layer ST. In other words, the stack patterns STP may vertically protrude above the device isolation layer ST.

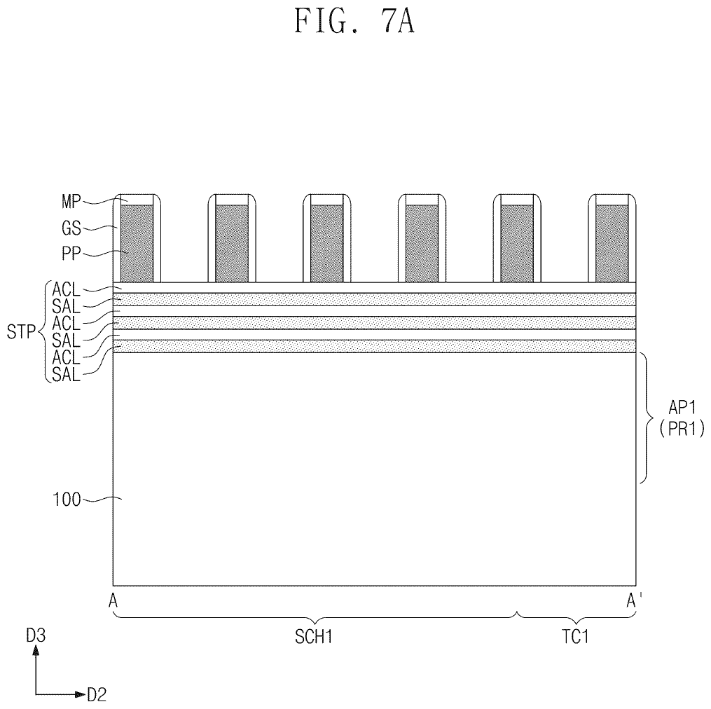

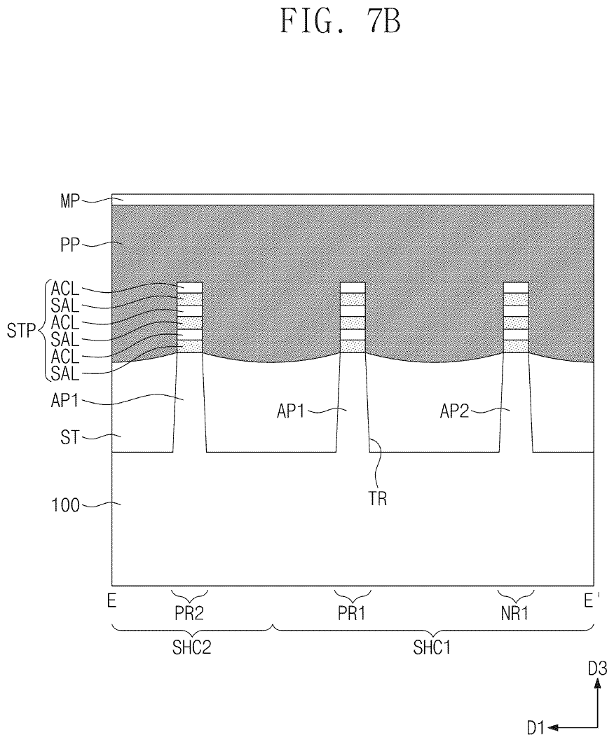

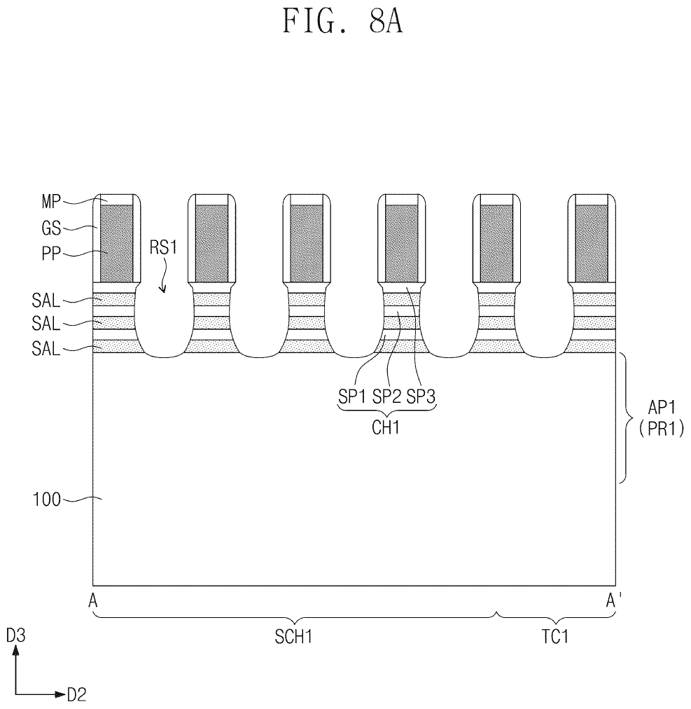

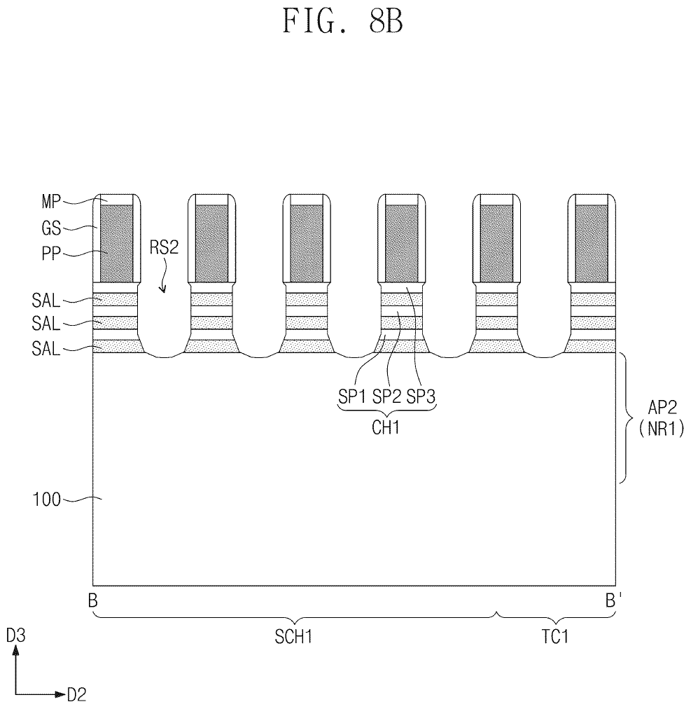

Referring to FIGS. 7A and 7B, sacrificial patterns PP intersecting the stack patterns STP may be formed on the substrate 100. Each of the sacrificial patterns PP may be formed to have a line shape or bar shape extending in the first direction D1. The sacrificial patterns PP may be arranged at a first pitch in the second direction D2.

For example, the formation of the sacrificial patterns PP may include forming a sacrificial layer on an entire top surface of the substrate 100, forming hard mask patterns MP on the sacrificial layer, and patterning the sacrificial layer using the hard mask patterns MP as etch masks. The sacrificial layer may include polysilicon.

A pair of gate spacers GS may be formed on both sidewalls of each of the sacrificial patterns PP, respectively. The formation of the gate spacers GS may include conformally forming a gate spacer layer on an entire top surface of the substrate 100, and anisotropically etching the gate spacer layer. The gate spacer layer may include at least one of SiCN, SiCON, or SiN. In certain example embodiments, the gate spacer layer may be formed of a multi-layer including at least two of SiCN, SiCON, or SiN.

Referring to FIGS. 8A to 8C, first recesses RS1 may be formed in the stack pattern STP on the first active pattern AP1. Second recesses RS2 may be formed in the stack pattern STP on the second active pattern AP2. The device isolation layer ST at both sides of each of the first and second active patterns AP1 and AP2 may be further recessed during the formation of the first and second recesses RS1 and RS2 (see FIG. 8C).

For example, the stack pattern STP on the first active pattern AP1 may be etched using the hard mask patterns MP and the gate spacers GS as etch masks to form the first recesses RS1. The first recess RS1 may be formed between a pair of the sacrificial patterns PP. The second recesses RS2 in the stack pattern STP on the second active pattern AP2 may be formed by the same method as the first recesses RS1.

First to third semiconductor patterns SP1, SP2 and SP3 stacked sequentially may be formed from the first semiconductor layers ACL between the first recesses RS1 adjacent to each other. First to third semiconductor patterns SP1, SP2 and SP3 stacked sequentially may be formed from the first semiconductor layers ACL between the second recesses RS2 adjacent to each other. The first to third semiconductor patterns SP1, SP2 and SP3 between the first recesses RS1 adjacent to each other may constitute a first channel pattern CH1. The first to third semiconductor patterns SP1, SP2 and SP3 between the second recesses RS2 adjacent to each other may constitute a second channel pattern CH2.

Referring to FIGS. 9A to 9C, first source/drain patterns SD1 may be formed in the first recesses RS1, respectively. For example, a first selective epitaxial growth (SEG) process may be performed using an inner surface of the first recess RS1 as a seed layer to form a buffer layer BFL. The buffer layer BFL may be grown using the first to third semiconductor patterns SP1, SP2 and SP3 and the substrate 100 exposed by the first recess RS1 as a seed. For example, the first SEG process may include a chemical vapor deposition (CVD) process or a molecular beam epitaxy (MBE) process.

The buffer layer BFL may include a semiconductor element (e.g., SiGe) of which a lattice constant is greater than a lattice constant of a semiconductor element of the substrate 100. The buffer layer BFL may contain a relatively low concentration of germanium (Ge). In certain embodiments of the inventive concepts, the buffer layer BFL may contain silicon (Si) except germanium (Ge). A concentration of germanium (Ge) of the buffer layer BFL may range from 0 at % to 30 at %.

A second SEG process may be performed on the buffer layer BFL to form a main layer MAL. The main layer MAL may be formed to completely or substantially fill the first recess RS1. The main layer MAL may contain a relatively high concentration of germanium (Ge). For example, a concentration of germanium (Ge) of the main layer MAL may range from 30 at % to 70 at %.

In some example embodiments of the inventive concepts, a third SEG process may be performed on the main layer MAL to form a capping layer. The capping layer may include silicon (Si). A concentration of silicon (Si) of the capping layer may range from 98 at % to 100 at %.

Dopants (e.g., boron, gallium or indium) for allowing the first source/drain pattern SD1 to have a p-type may be injected in-situ during the formation of the buffer layer BFL and the main layer MAL. In some example embodiments, the dopants may be injected or implanted into the first source/drain pattern SD1 after the formation of the first source/drain pattern SD1.

Second source/drain patterns SD2 may be formed in the second recesses RS2, respectively. For example, the second source/drain pattern SD2 may be formed by performing a SEG process using an inner surface of the second recess RS2 as a seed layer. For example, the second source/drain pattern SD2 may include the same semiconductor element (e.g., Si) as the substrate 100.

Dopants (e.g., phosphorus, arsenic or antimony) for allowing the second source/drain pattern SD2 to have an n-type may be injected in-situ during the formation of the second source/drain pattern SD2. In some example embodiments, the dopants may be injected or implanted into the second source/drain pattern SD2 after the formation of the second source/drain pattern SD2.

In some example embodiments of the inventive concepts, before the formation of the second source/drain pattern SD2, portions of the second semiconductor layers SAL exposed by the second recess RS2 may be replaced with an insulating material to form inner spacers IP. Thus, the inner spacers IP may be formed between the second source/drain pattern SD2 and the second semiconductor layers SAL, respectively.

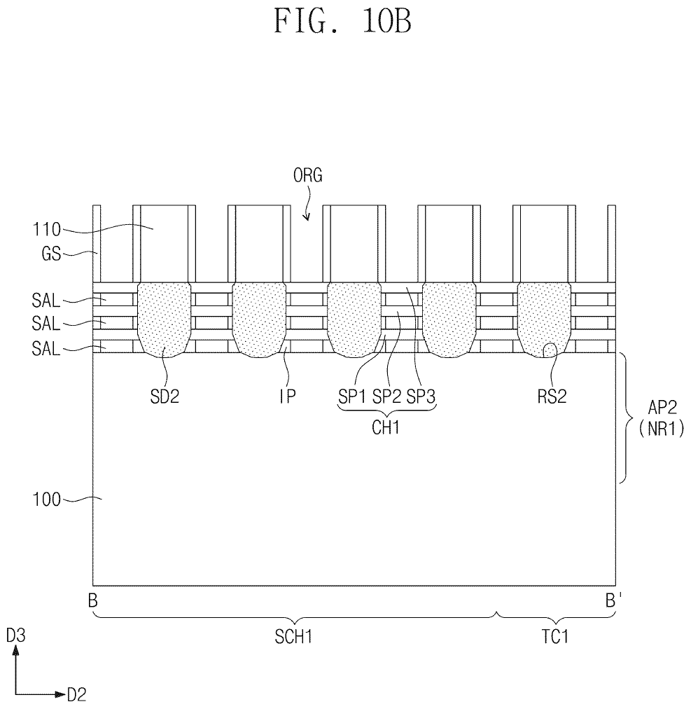

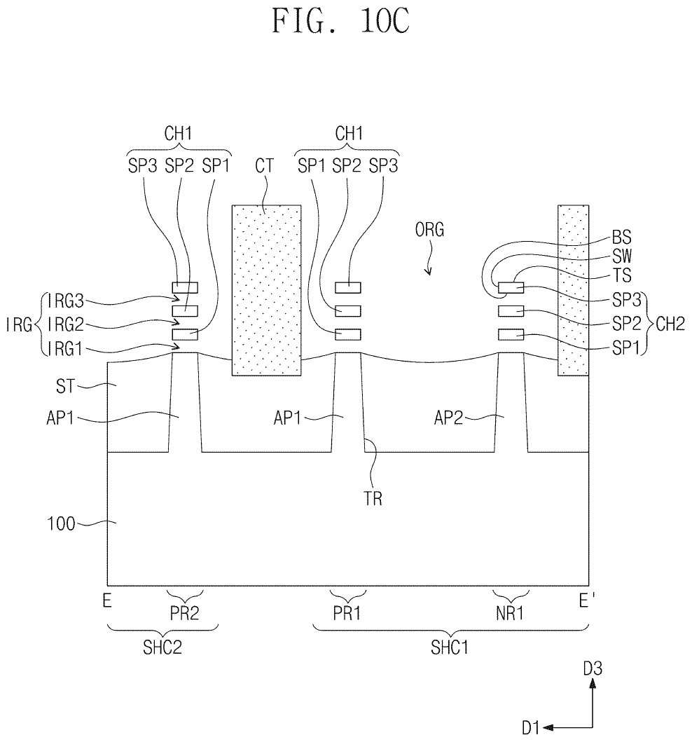

Referring to FIGS. 10A to 10C, a first interlayer insulating layer 110 may be formed to cover the first and second source/drain patterns SD1 and SD2, the hard mask patterns MP and the gate spacers GS. For example, the first interlayer insulating layer 110 may include a silicon oxide layer.

The first interlayer insulating layer 110 may be planarized to expose top surfaces of the sacrificial patterns PP. The planarization of the first interlayer insulating layer 110 may be performed using an etch-back process or a chemical mechanical polishing (CMP) process. The hard mask patterns MP may be completely removed during the planarization process. Thus, a top surface of the first interlayer insulating layer 110 may be substantially coplanar with the top surfaces of the sacrificial patterns PP and top surfaces of the gate spacers GS.

A region of the sacrificial pattern PP may be selectively opened using a photolithography process. For example, a region of the sacrificial pattern PP on a boundary between the first and second single height cells SHC1 and SHC2 may be selectively opened. The opened region of the sacrificial pattern PP may be selectively etched and thus may be removed. A space formed by the removal of the sacrificial pattern PP may be filled with an insulating material to form a gate cutting pattern CT (see FIG. 10C).

Remaining exposed portions of the sacrificial patterns PP may be selectively removed. An outer region ORG exposing the first and second channel patterns CH1 and CH2 may be formed by the removal of the sacrificial pattern PP (see FIG. 10C). The removal of the sacrificial patterns PP may include performing a wet etching process using an etching solution capable of selectively etching polysilicon.

The second semiconductor layers SAL exposed through the outer region ORG may be selectively removed to form inner regions IRG (see FIG. 10C). For example, an etching process of selectively etching the second semiconductor layers SAL may remove the second semiconductor layers SAL while leaving the first to third semiconductor patterns SP1, SP2 and SP3. The etching process may have a high etch rate with respect to silicon-germanium having a relatively high germanium concentration. For example, the etching process may have a high etch rate with respect to silicon-germanium having a germanium concentration greater than 10 at %.

The second semiconductor layers SAL on the first and second PMOSFET regions PR1 and PR2 and the first and second NMOSFET regions NR1 and NR2 may be completely removed during the etching process. The etching process may be a wet etching process. An etching material used in the etching process may quickly remove the second semiconductor layer SAL having a relatively high germanium concentration. Meanwhile, the first source/drain patterns SD1 on the first and second PMOSFET regions PR1 and PR2 may be protected by the buffer layer BFL having a relatively low germanium concentration during the etching process.

Referring again to FIG. 10C, because the second semiconductor layers SAL are selectively removed, the stacked first to third semiconductor patterns SP1, SP2 and SP3 may remain on each of the first and second active patterns AP1 and AP2. First to third inner regions IRG1, IRG2 and IRG3 may be formed by the removal of the second semiconductor layers SAL.

In detail, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring to FIGS. 11A to 11D, a gate insulating layer GI may be conformally formed on the exposed first to third semiconductor patterns SP1, SP2 and SP3. A gate electrode GE may be formed on the gate insulating layer GI. The gate electrode GE may include first to third inner electrodes PO1, PO2 and PO3 formed in the first to third inner regions IRG1, IRG2 and IRG3, respectively, and an outer electrode PO4 formed in the outer region ORG.

The gate electrode GE may be recessed to reduce its height. Upper portions of the gate cutting patterns CT may also be slightly recessed during the recessing of the gate electrode GE. A gate capping pattern GP may be formed on the recessed gate electrode GE.

An isolation structure DB may be formed on a boundary between the cells. The isolation structure DB may penetrate the gate capping pattern GP and the gate electrode GE and may extend into the active pattern AP1 or AP2. The isolation structure DB may include an insulating material such as silicon oxide or silicon nitride. A second interlayer insulating layer 120 may be formed on the first interlayer insulating layer 110. The second interlayer insulating layer 120 may include a silicon oxide layer.

Referring again to FIG. 11D, through-holes TVH may be formed to penetrate the first and second interlayer insulating layers 110 and 120 and may expose the substrate 100. For example, at least one through-hole TVH may be formed on a boundary between the first and second tab cells TC1 and TC2. The through-hole TVH may be formed between a pair of the first active patterns AP1. A width of the through-hole TVH may become progressively less toward the substrate 100.

A bottom TVHb of the through-hole TVH may be lower than a top surface of the substrate 100. In some example embodiments of the inventive concepts, the top surface of the substrate 100 may mean a bottom of the trench TR. An upper spacer TSP may be formed on an inner sidewall of the through-hole TVH. The upper spacer TSP may be formed of a silicon-based insulating material.

A first metal pattern BMP may be formed in a lower portion of the through-hole TVH. The formation of the first metal pattern BMP may include performing a deposition process such as a PVD process, a CVD process, and/or an ALD process. The first metal pattern BMP may be formed of a metal having a robust property in a cleaning process and an etching process of an insulating layer. For example, the first metal pattern BMP may be formed of at least one selected from a group consisting of silver (Ag), gold (Au), platinum (Pt), copper (Cu), iridium (Ir), ruthenium (Ru), scandium (Sc), yttrium (Y), and lanthanum (La).

The first metal pattern BMP may be selectively formed in the lower portion of the through-hole TVH. An upper portion of the through-hole TVH may still remain as an empty space. For example, the first metal pattern BMP may be formed using a bottom-up growth method in which a material is deposited in the third direction D3.

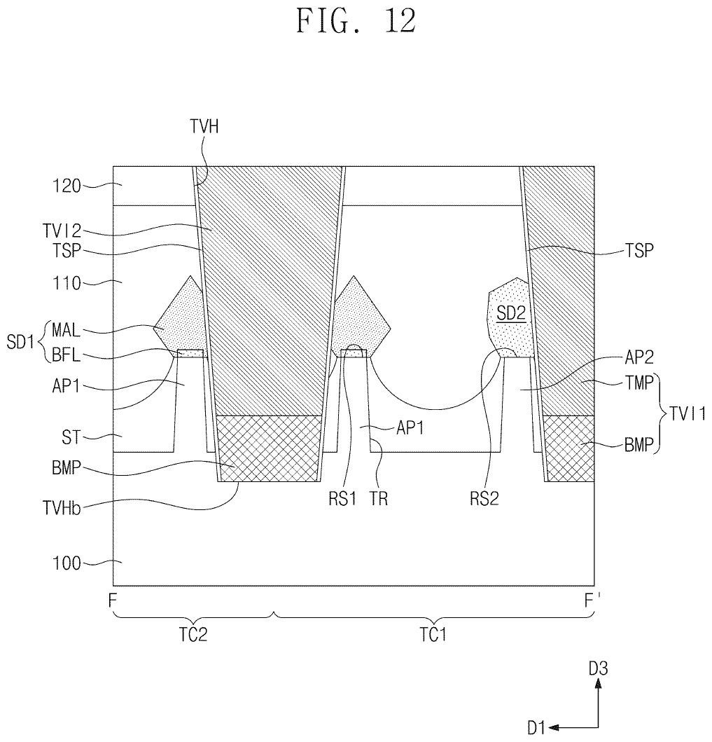

Referring to FIG. 12, a second metal pattern TMP may be formed on the first metal pattern BMP. The second metal pattern TMP may be formed to fill the through-hole TVH. The second metal pattern TMP may be formed of a metal having a resistance lower than that of the first metal pattern BMP. For example, the second metal pattern TMP may include at least one selected from a group consisting of tungsten (W), molybdenum (Mo), ruthenium (Ru), aluminum (Al), titanium (Ti), and tantalum (Ta).

The first metal pattern BMP and the second metal pattern TMP may constitute each of through-vias TVI1 to TVI3. A volume of the second metal pattern TMP may be greater than a volume of the first metal pattern BMP. In other words, each of the through-vias TVI1 to TVI3 may have a relatively small resistivity, due to the second metal pattern TMP.

Thereafter, as described above with reference to FIGS. 4 and 5A to 5F, active contacts AC may be formed to penetrate the second interlayer insulating layer 120 and the first interlayer insulating layer 110, and the active contacts AC may be electrically connected to the first and second source/drain patterns SD1 and SD2. A gate contact GC may be formed to penetrate the second interlayer insulating layer 120 and the gate capping pattern GP, and the gate contact GC may be electrically connected to the gate electrode GE. A third interlayer insulating layer 130 may be formed on the active contacts AC and the gate contacts GC. A first metal layer M1 may be formed in the third interlayer insulating layer 130. The first metal layer M1 may include first to third power interconnection lines M1_R1, M1_R2 and M1_R3 electrically connected to the first to third through-vias TVI1 to TVI3, respectively. A fourth interlayer insulating layer 140 may be formed on the third interlayer insulating layer 130. A second metal layer M2 may be formed in the fourth interlayer insulating layer 140.

Referring to FIG. 13, after a BEOL process is completed, the substrate 100 may be turned over to expose a bottom surface 100b of the substrate 100. A planarization process may be performed on the bottom surface 100b of the substrate 100 to reduce a thickness of the substrate 100. The planarization process may be performed until the first metal pattern BMP is exposed. A cleaning process may be performed on the bottom surface 100b of the substrate 100.

The cleaning process may remove particles and various impurities, which remain on the substrate 100. The cleaning process may be performed using at least one cleaning solution selected from a group consisting of standard clean-1 (SC-1), dilute hydrofluoric acid (DHF), BOE (LAL), and diluted sulfate peroxide (DSP).

Due to the planarization process and the cleaning process, an end portion (e.g., a bottom portion) BMPu of the first metal pattern BMP may protrude above (e.g., beyond) the bottom surface 100b of the substrate 100. In other words, the end portion BMPu of the first metal pattern BMP may be exposed.

Because the first metal pattern BMP is formed of the robust metal which is not well etched by the cleaning solution as described above, the first metal pattern BMP may not be removed by the planarization process and the cleaning process but may remain. Thus, the end portion BMPu of the first metal pattern BMP may protrude above the bottom surface 100b of the substrate 100 and may remain.

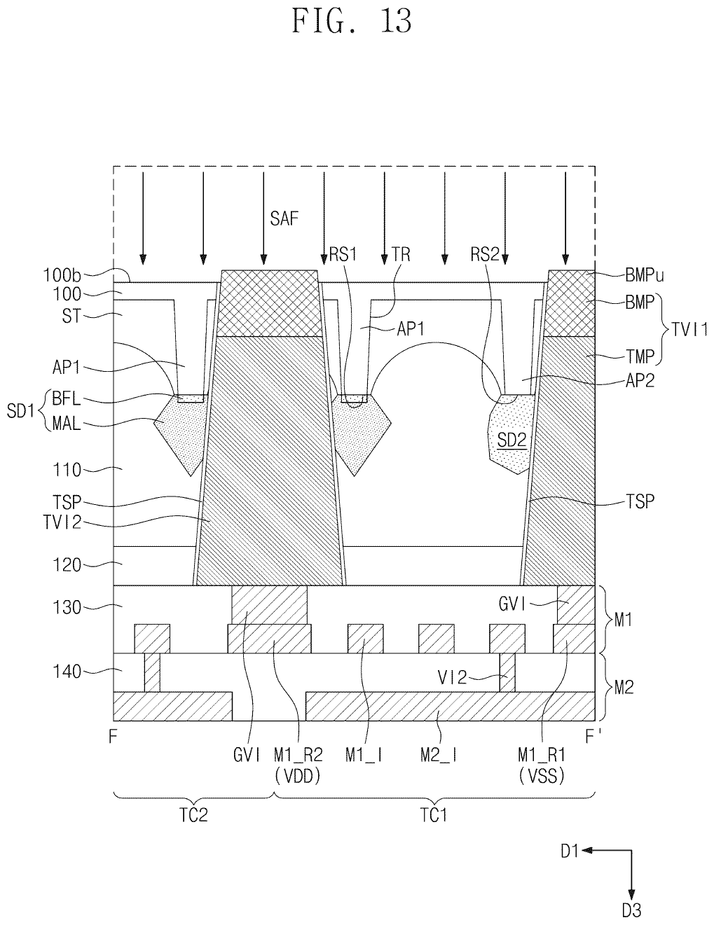

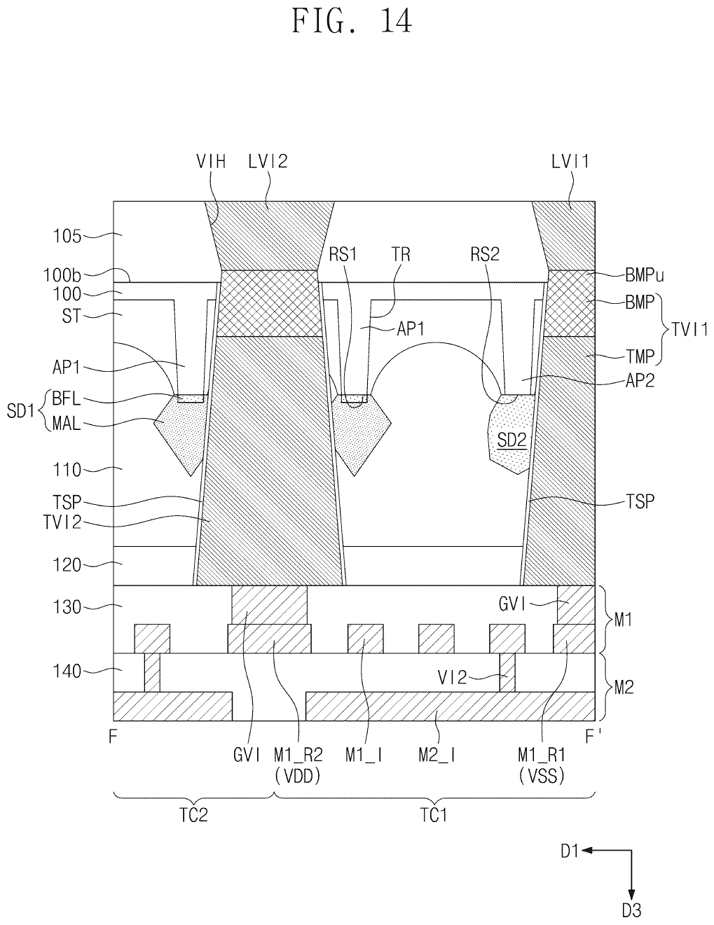

Referring to FIG. 14, a lower insulating layer 105 may be formed on the bottom surface 100b of the substrate 100. The lower insulating layer 105 may be patterned to form via holes VIH. Each of the via holes VIH may expose the end portion BMPu of the first metal pattern BMP. A cleaning process may be performed after the formation of the via holes VIH. Because the first metal pattern BMP is formed of the robust metal as described above, the first metal pattern BMP may not be removed during the cleaning process but may remain.

The via holes VIH may be filled with a metal to form first to third lower through-vias LVI1, LVI2 and LVI3 in the via holes VIH, respectively. The first to third lower through-vias LVI1, LVI2 and LVI3 may be directly connected to the first to third through-vias TVI1, TVI2 and TVI3, respectively. Each of the first to third lower through-vias LVI1, LVI2 and LVI3 may be in direct contact with the end portion BMPu of the first metal pattern BMP of a corresponding one of the first to third through-vias TVI1, TVI2 and TVI3.

Thereafter, a power delivery network layer PDN may be formed on the lower insulating layer 105. The power delivery network layer PDN may be formed to apply a source voltage or a drain voltage to each of the first to third power interconnection lines M1_R1, M1_R2 and M1_R3.

Hereinafter, various example embodiments of the inventive concepts will be described. In the following example embodiments of the inventive concepts, the descriptions to the same technical features as mentioned with reference to FIGS. 4 and 5A to 5F will be omitted and differences between the following example embodiments and the example embodiments of FIGS. 4 and 5A to 5F will be mainly described, for the purpose of ease and convenience in explanation.

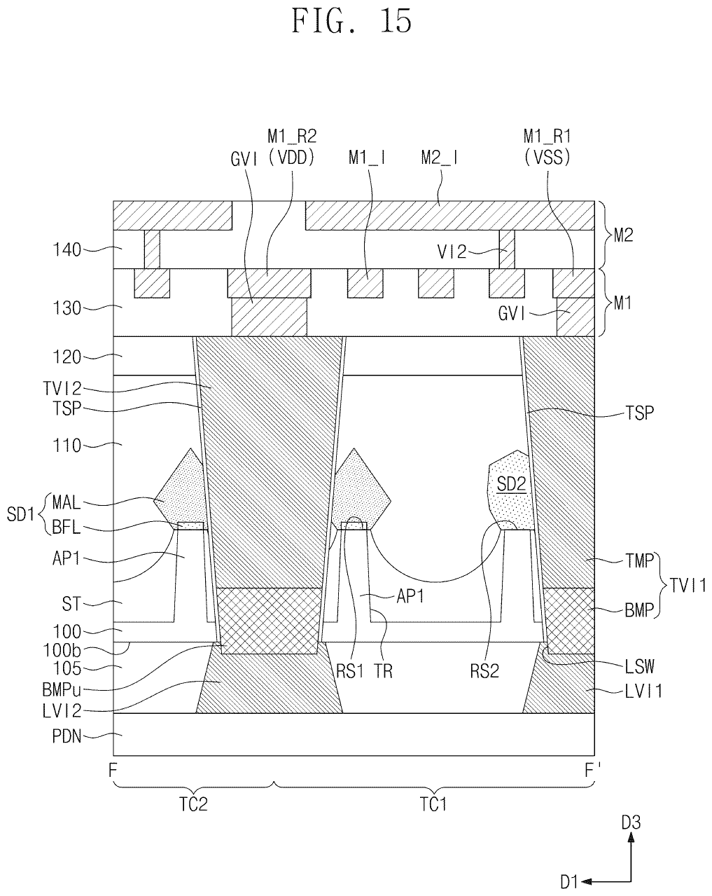

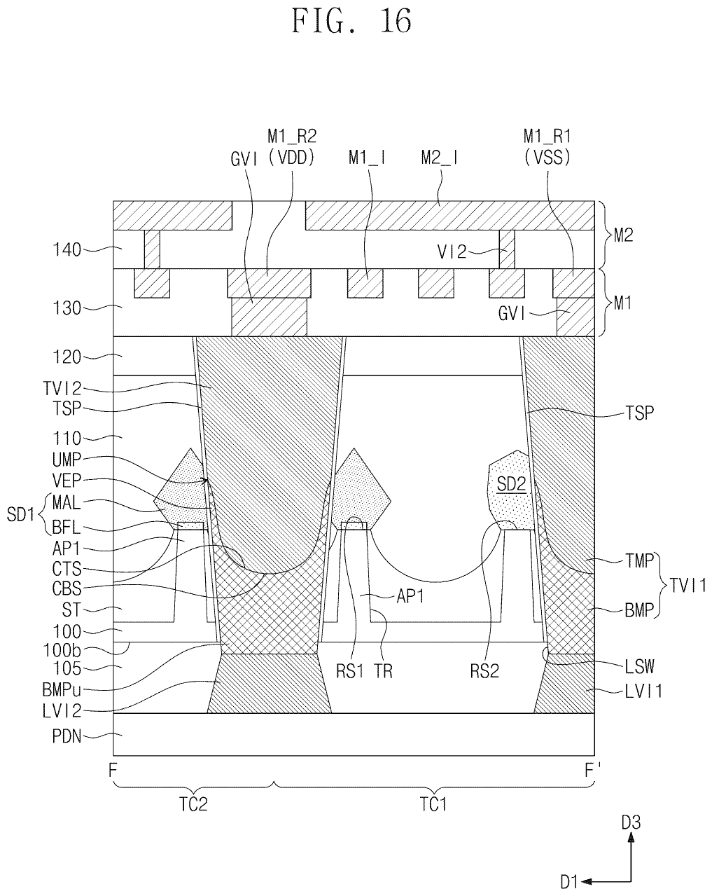

FIGS. 15 and 16 are cross-sectional views taken along the line F-F′ of FIG. 4 to illustrate semiconductor devices according to some example embodiments of the inventive concepts. Referring to FIG. 15, a lower portion of each of the through-vias TVI1 to TVI3 (e.g., the end portion BMPu of the first metal pattern BMP) may be lower than the bottom surface 100b of the substrate 100.

Each of lower through-vias LVI1 to LVI3 may surround and be in contact with the end portion BMPu of the first metal pattern BMP. According to the example embodiment of FIG. 15, a width (or diameter) of each of the lower through-vias LVI1 to LVI3 may be greater than a width (or diameter) of the end portion BMPu of the first metal pattern BMP of a corresponding one of the first to third through-vias TVI1, TVI2 and TVI3. For example, each of the lower through-vias LVI1 to LVI3 may be in direct contact with a lower sidewall LSW of the first metal pattern BMP of a corresponding one of the first to third through-vias TVI1, TVI2 and TVI3.

According to the example embodiment of FIG. 15, a contact area between each of the lower through-vias LVI1 to LVI3 and a corresponding one of the through-vias TVI1 to TVI3 may be increased. Thus, a contact resistance between each of the lower through-vias LVI1 to LVI3 and a corresponding one of the through-vias TVI1 to TVI3 may be reduced, and electrical characteristics of the semiconductor device may be improved.

Referring to FIG. 16, a first metal pattern BMP of each of the through-vias TVI1 to TVI3 may include a vertical extension VEP disposed at a side thereof. The vertical extension VEP may extend in the third direction D3 along the upper spacer TSP. The vertical extension VEP may be disposed between the upper spacer TSP and the second metal pattern TMP. An uppermost portion UMP of the vertical extension VEP may be lower than a top surface of the second metal pattern TMP.

The first metal pattern BMP may have a concave top surface CTS due to the vertical extension VEP. The second metal pattern TMP may have a convex bottom surface CBS being in contact with the concave top surface CTS of the first metal pattern BMP.

A contact area between the first metal pattern BMP and the second metal pattern TMP may be increased by the vertical extension VEP. Thus, a resistance in each of the through-vias TVI1 to TVI3 may be reduced, and electrical characteristics of the semiconductor device may be improved.

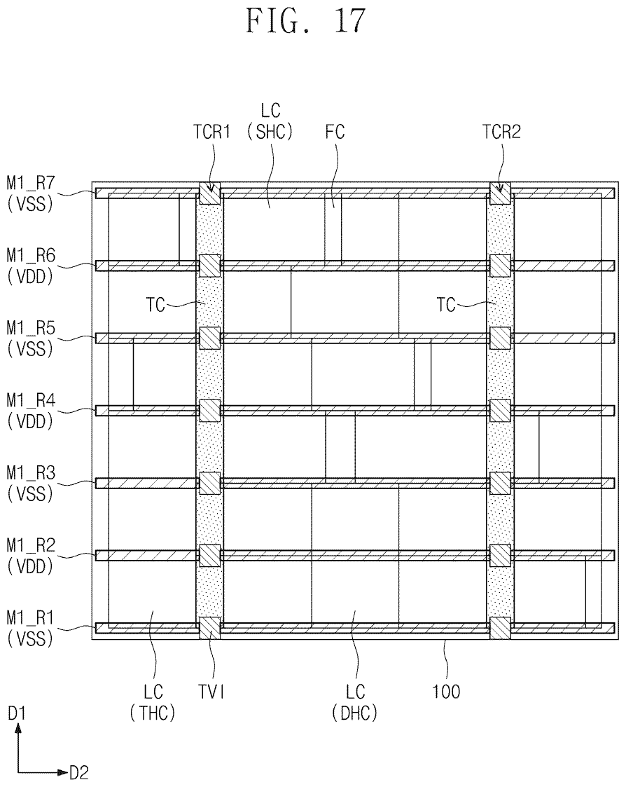

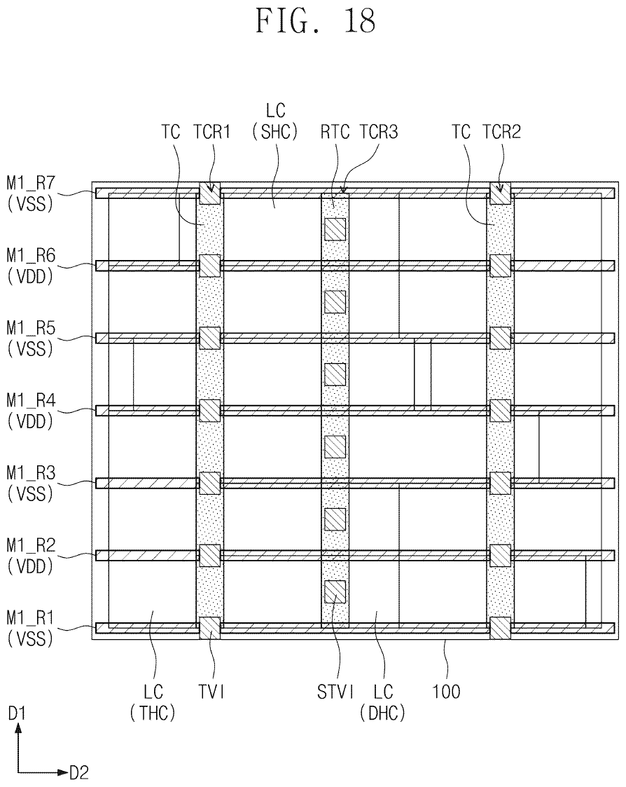

FIGS. 17 and 18 are plan views illustrating arrangements of tab cells and logic cells of semiconductor devices according to some example embodiments of the inventive concepts.

Referring to FIG. 17, first to seventh power interconnection lines M1_R1 to M1_R7 may be arranged in the first direction D1 on a substrate 100. A first tab cell track TCR1 and a second tab cell track TCR2 may be provided on the substrate 100. Each of the first and second tab cell tracks TCR1 and TCR2 may extend in the first direction D1. The first and second tab cell tracks TCR1 and TCR2 may be arranged in the second direction D2 at a certain pitch.

Tab cells TC may be arranged in the first direction D1 on each of the first and second tab cell tracks TCR1 and TCR2. For example, each of the tab cells TC according to an example embodiment may be the tab cell TC1 or TC2 of FIG. 4.

Through-vias TVI may be arranged in the first direction D1 on each of the first and second tab cell tracks TCR1 and TCR2. The through-vias TVI may be connected to the first to seventh power interconnection lines M1_R1 to M1_R7, respectively. The through-vias TVI may be used to apply voltages from the power delivery network layer PDN to the first to seventh power interconnection lines M1_R1 to M1_R7.

Logic cells LC and filler cells FC may be disposed on the substrate 100. The logic cells LC may be disposed on a remaining region on which the tab cells TC are not disposed. The logic cells LC may be disposed on the substrate 100 on the basis of a designed circuit. For example, the logic cells LC may include at least one single height cell SHC, at least one double height cell DHC, and at least one triple height cell THC. The filler cell FC may fill an empty space between adjacent logic cells LC. The filler cell FC may be a dummy cell.

Referring to FIG. 18, a third tab cell track TCR3 may be provided between the first and second tab cell tracks TCR1 and TCR2. Routing tab cells RTC may be arranged in the first direction D1 on the third tab cell track TCR3. Each of the routing tab cells RTC may include a signal through-via STVI. A shape of the signal through-via STVI may be substantially the same as the shape of the through-via TVI described above. The signal through-via STVI may be provided between a PMOSFET region and an NMOSFET region. The signal through-via STVI may be electrically connected to the power delivery network layer PDN.

The signal through-via STVI may be electrically connected to the logic cell LC adjacent to the third tab cell track TCR3. For example, a signal may be transmitted from the adjacent logic cell LC to the routing tab cell RTC through the first interconnection line M1_I in the first metal layer M1. The signal transmitted to the routing tab cell RTC may be transmitted to another logic cell LC through the power delivery network layer PDN. In other words, the power delivery network layer PDN may be configured to provide voltages to the power interconnection lines M1_R1 to M1_R7 and may also be configured to provide routing for signal transmission.

Due to the routing tab cell RTC according to the present example embodiment, the semiconductor device may use the power delivery network layer PDN under the substrate 100 as well as a BEOL layer (e.g., the first and second metal layers M1 and M2) for signal transmission. Thus, an interconnection congestion of the BEOL layer may be reduced, and an integration density of the semiconductor device may be improved. In addition, a signal transmission resistance of the semiconductor device may be reduced to improve electrical characteristics.

In the semiconductor device according to the inventive concepts, the through-via may be realized as a stack structure including the first metal pattern having the robust property and the second metal pattern having the low resistivity. Thus, process defects may be mitigated or prevented. Thus, a yield of the semiconductor device may be improved, and a resistance of the through-via may be reduced, thereby improving electrical characteristics of the semiconductor device.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor device comprising:
an active pattern on a substrate;
a source/drain pattern on the active pattern;
a first metal layer on the source/drain pattern, the first metal layer comprising a power interconnection line;
a through-via electrically connected to the power interconnection line, the through-via vertically extending to penetrate the substrate;
a power delivery network layer on a bottom surface of the substrate; and
a lower through-via between the power delivery network layer and the through-via,
wherein the through-via comprises,
a first metal pattern connected to the lower through-via, and
a second metal pattern stacked on the first metal pattern,
wherein a density of the first metal pattern is greater than a density of the second metal pattern, and
wherein a resistivity of the first metal pattern is greater than a resistivity of the second metal pattern.

2. The semiconductor device of claim 1, wherein an end portion of the first metal pattern is lower than the bottom surface of the substrate.

3. The semiconductor device of claim 2, wherein the lower through-via surrounds the end portion of the first metal pattern.

4. The semiconductor device of claim 1, wherein
the first metal pattern and the second metal pattern include different metals,
the first metal pattern includes at least one selected from a group consisting of silver (Ag), gold (Au), platinum (Pt), copper (Cu), iridium (Ir), ruthenium (Ru), scandium (Sc), yttrium (Y), and lanthanum (La), and
the second metal pattern includes at least one selected from a group consisting of tungsten (W), molybdenum (Mo), ruthenium (Ru), aluminum (Al), titanium (Ti), and tantalum (Ta).

5. The semiconductor device of claim 1, wherein a volume of the second metal pattern is greater than a volume of the first metal pattern in the through-via.

6. The semiconductor device of claim 1, wherein
the source/drain pattern includes a pair of source/drain patterns adjacent to each other, and
the through-via penetrates an interlayer insulating layer between the pair of source/drain patterns.

7. The semiconductor device of claim 1, wherein
a width of the through-via becomes progressively less toward the power delivery network layer, and
a width of the lower through-via becomes progressively greater toward the power delivery network layer.

8. The semiconductor device of claim 1, wherein
the first metal pattern includes a vertical extension portion at a side thereof,
the first metal pattern has a concave top surface due to the vertical extension portion, and
the second metal pattern has a convex bottom surface being in contact with the concave top surface of the first metal pattern.

9. The semiconductor device of claim 1, further comprising:
a spacer on a sidewall of the through-via,
wherein an uppermost portion of the first metal pattern is lower than a top surface of the second metal pattern, and
wherein at least a portion of the second metal pattern is in direct contact with the spacer.

10. The semiconductor device of claim 1, wherein the power delivery network layer is configured to apply a source voltage or a drain voltage to the power interconnection line.

11. A semiconductor device comprising:
a plurality of power interconnection lines on a substrate, the power interconnection lines arranged in a first direction, and the power interconnection lines extending in a second direction in parallel to each other;
a plurality of logic cells two-dimensionally arranged on the substrate;
a plurality of tab cells arranged in the first direction on the substrate; and
a power delivery network layer under the substrate,
wherein the plurality of tab cells comprises,
a plurality of through-vias electrically connected to the plurality of power interconnection lines, respectively, and
a plurality of lower through-vias electrically connecting the plurality of through-vias to the power delivery network layer, respectively,
wherein the power delivery network layer is configured to apply voltages to the plurality of power interconnection lines through the through-vias and the lower through-vias,
wherein each of the through-vias comprises,
a first metal pattern being in contact with a corresponding one of the lower through-vias; and
a second metal pattern stacked on the first metal pattern, and
wherein a resistivity of the first metal pattern is greater than a resistivity of the second metal pattern.

12. The semiconductor device of claim 11, wherein
an end portion of the first metal pattern is lower than a bottom surface of the substrate, and
a corresponding one of the lower through-vias is in contact with the end portion.

13. The semiconductor device of claim 11, wherein a volume of the second metal pattern is greater than a volume of the first metal pattern in a corresponding one of the through-vias.

14. The semiconductor device of claim 11, wherein an etch resistance of the first metal pattern to dilute hydrofluoric acid (DHF) or diluted sulfate peroxide (DSP) is greater than an etch resistance of the second metal pattern to the DHF or the DSP.

15. The semiconductor device of claim 11, further comprising:
a spacer on a sidewall of a respective one of the through-vias,
wherein an uppermost portion of the first metal pattern is lower than a top surface of the second metal pattern, and
wherein at least a portion of the second metal pattern is in direct contact with the spacer.

16. A semiconductor device comprising:
a first power interconnection line and a second power interconnection line on a substrate, the first and second power interconnection lines spaced apart from each other in a first direction, and the first and second power interconnection lines extending in a second direction in parallel to each other;
a logic cell and a tab cell between the first and second power interconnection lines, the logic cell and the tab cell adjacent to each other in the second direction;
a first active pattern and a second active pattern on the logic cell, the first and second active patterns spaced apart from each other in the first direction;
a first channel pattern and a first source/drain pattern on the first active pattern;
a second channel pattern and a second source/drain pattern on the second active pattern, the second source/drain pattern having a conductivity type different from that of the first source/drain pattern;
a gate electrode on the first and second channel patterns;
a gate insulating layer between the gate electrode and the first and second channel patterns;
a gate spacer on a sidewall of the gate electrode;
a gate capping pattern on a top surface of the gate electrode;
an interlayer insulating layer covering the first and second source/drain patterns and the gate capping pattern;
an active contact penetrating the interlayer insulating layer and electrically connected to at least one of the first and second source/drain patterns;
a metal-semiconductor compound layer between the active contact and the at least one of the first and second source/drain patterns;
a gate contact penetrating the interlayer insulating layer and the gate capping pattern and electrically connected to the gate electrode;
a first through-via and a second through-via on the tab cell, the first and second through-vias electrically connected to the first and second power interconnection lines, respectively;
a power delivery network layer on a bottom surface of the substrate; and
a first lower through-via and a second lower through-via between the power delivery network layer and the first and second through-vias, respectively,
wherein each of the first and second through-vias comprises,
a first metal pattern being in contact with a corresponding one of the first and second lower through-vias, and
a second metal pattern stacked on the first metal pattern, and
wherein the first metal pattern and the second metal pattern include different metals.

17. The semiconductor device of claim 16, wherein
a width of each of the first and second through-vias becomes progressively less toward the power delivery network layer, and
a width of each of the first and second lower through-vias becomes progressively greater toward the power delivery network layer.

18. The semiconductor device of claim 16, wherein each of the first and second channel patterns comprises a plurality of semiconductor patterns stacked sequentially and spaced apart from each other.

19. The semiconductor device of claim 16, further comprising:
a spacer on a sidewall of each of the first and second through-vias,
wherein an uppermost portion of the first metal pattern is lower than a top surface of the second metal pattern, and
wherein at least a portion of the second metal pattern is in direct contact with the spacer.

20. The semiconductor device of claim 16, further comprising:
interconnection lines on the logic cell,
wherein the interconnection lines are electrically connected to the active contact and the gate contact, respectively, and
wherein the interconnection lines are at a same level as the first and second power interconnection lines.
